(19) United States
(12) Patent Application Publication
(10) Pub. No.: US 2011/0177694 A1
(43) Pub. Date: Jul. 21, 2011

(54) Switchable Neutral Beam Source

(75) Inventors: Lee Chen, Cedar Creek, TX (US); Merritt Funk, Austin, TX (US)

(73) Assignee: Tokyo Electron Limited, Tokyo (JP)

(21) Appl. No.: 12/688,721

(22) Filed: Jan. 15, 2010

(51) Int. Cl. H01L 21/467

(52) U.S. Cl. 438/710; 156/345.24; 257/E21.486

(57) ABSTRACT

The invention can provide apparatus and methods of processing a substrate in real-time using a switchable quasi-neutral beam system to improve the etch resistance of photoresist layer. In addition, the improved photoresist layer can be used in an etch procedure to more accurately control gate and/or spacer critical dimensions (CDs), to control gate and/or spacer CD uniformity, and to eliminate line edge roughness (LER) and line width roughness (LWR).

### BACKGROUND OF THE INVENTION

1. Field of the Invention

The present invention relates to substrate processing, and more particularly to improving the substrate processing using a switchable neutral beam source.

2. Description of the Related Art

During semiconductor processing, plasma is often utilized to assist etch processes by facilitating the anisotropic removal of material along fine lines or within vias (or contacts) patterned on a semiconductor substrate. Furthermore, plasma is utilized to enhance the deposition of thin films by providing improved mobility of adatoms on a semiconductor substrate.

Once the plasma is formed, selected surfaces of the substrate are etched by the plasma. The process is adjusted to achieve appropriate conditions, including an appropriate concentration of desirable reactant and ion populations to etch various features (e.g., trenches, vias, contacts, etc.) in the selected regions of the substrate. Such substrate materials where etching is required include silicon dioxide (SiO₂), low-k dielectric materials, poly-silicon, and silicon nitride.

However, the use of plasma (i.e., electrically charged particles), itself, produces problems in the manufacture of semiconductor devices. As devices have become smaller and integration densities have increased, breakdown voltages of insulation and isolation structures therein have, in many instances, been markedly reduced, often to much less than ten volts. For example, some integrated circuit (IC) device designs call for insulators of sub-micron thicknesses.

At the same time, the reduction of the size of structures reduces the capacitance value of the insulation or isolation structures, and relatively fewer charged particles are required to develop an electric field of sufficient strength to break down insulation or isolation structures. Therefore, the tolerance of semiconductor structures for the charge carried by particles impinging on them during the manufacturing process, such as a dry plasma etching process, has become quite limited and the structures for dissipating such charges during manufacture are sometimes required, often complicating the design of the semiconductor device.

While this problem could be avoided by performing processing with neutrally charged particles, the charge of an ion or electron is the only property by which the motion of these particles can be effectively manipulated and guided. Therefore, an ion must remain in a charged state until its trajectory can be established and the energy of the ion must be sufficient that its trajectory will remain unchanged when neutralized by an electron. Even then, the trajectory may be altered and the flux of a neutral beam can be severely depleted by collisions with other particles which may or may not have been neutralized and which may have trajectories that are not precisely parallel.

Because of this need, neutral beam sources have been developed to produce a beam of neutrally charged particles of arbitrary energy that may be as low as a few electron volts and as large as tens of thousands of electron volts or larger.

### SUMMARY OF THE INVENTION

The invention relates to a Switchable Quasi-Neutral Beam (SQNB) source that can be used for a substrate treatment procedure that can include masking layer curing, drying, shrinking, correcting, and/or hardening procedures, etch procedures, ashing procedures, cleaning procedures, deposition procedures. In some embodiments, the SQNB source can be used for curing and/or hardening a masking layer on a patterned substrate and for using the cured and/or hardened masking layer in a subsequent etching procedure for the patterned substrate.

The invention relates to a SQNB system and method for curing, drying, shrinking, correcting, and/or hardening a patterned masking layer on a substrate with a space-charge neutralized neutral beam activated process and etching the substrate using the cured, dried, shrunk, corrected, and/or hardened patterned masking layer. The SQNB system can include an upper plasma chamber for forming one or more different upper plasmas at one or more different upper plasma potentials, and a Switchable Quasi-Neutral Beam (SQNB) process chamber for forming one or more different SQNB process plasmas at one or more different SQNB plasma potentials that can be greater than the upper plasma potentials, and the SQNB process plasma is formed using electron flux from the upper plasma. Further, the SQNB system comprises a switchable substrate holder configured to position a substrate in the SQNB process chamber, to provide a first substrate-biasing configuration during a first SQNB procedure, and to provide a second substrate-biasing configuration during a second SQNB procedure.

The SQNB system can be configured to generate a first quasi-neutral beam during a first SQNB procedure and to generate a second quasi-neutral beam during a second SQNB procedure. The SQNB system can be configured to generate first SQNB plasma in the SQNB process chamber during a first SQNB procedure using a first set of neutralization beams and first process gasses and to generate second SQNB plasma in the SQNB process chamber during a second SQNB procedure using a second set of neutralization beams and second process gasses.

The invention can include a SQNB system that includes: a plasma generation chamber that includes an upper plasma region configured to receive a first process gas at a first flow rate; a first gas injection system coupled to the plasma generation chamber and configured to introduce the first process gas to the upper plasma region; a plasma generation system coupled to the plasma generation chamber and configured to generate an upper plasma at an upper plasma potential in the upper plasma region from the first process gas; a Switchable Quasi-neutral beam (SQNB) process chamber comprising a switchable plasma region disposed downstream of the upper plasma region and configured to receive at least one upper plasma species from the upper plasma region at a second flow rate; a separation member disposed between the upper plasma region and the switchable plasma region, wherein the separation member comprises one or more openings configured to allow an electron flux from the upper plasma region to the switchable plasma region to form a switchable plasma at a switchable plasma potential in the SQNB process chamber; a lower bias electrode coupled to the SQNB process chamber and configured to elevate the switchable plasma potential above the upper plasma potential in order to control the electron flux; a switchable substrate holder coupled to the SQNB process chamber and configured to support the substrate proximate the switchable plasma region; the switchable substrate holder coupled to a multi-position switch that is configured to be in a first position during a first SQNB procedure and to be in a second position during a second SQNB procedure; and a vacuum pumping system coupled to the SQNB process chamber. For example, the vacuum pumping system can be configured to pump the switchable plasma region in the SQNB process chamber to a first pressure during a first SQNB procedure, and can be configured to pump the switchable plasma region in the SQNB process chamber to a second pressure during a second SQNB procedure.

The invention can include a SQNB system that comprises: a plasma generation chamber and a plasma generation system configured to create a first upper plasma at a first upper plasma potential in an upper plasma region in the plasma generation chamber during a first SQNB procedure and are further configured to create a second upper plasma at a second upper plasma potential in an upper plasma region in the plasma generation chamber during an second SQNB procedure; the plasma generation chamber is configured to receive a first plasma generation gas at a first flow rate during a first SQNB procedure and is further configured to receive a second plasma generation gas at a second flow rate during an second SQNB procedure; SQNB process chamber comprising a switchable plasma region disposed downstream of the upper plasma region and configured to receive at least one upper plasma species from the upper plasma region during a first SQNB procedure and is further configured to receive at least one second plasma species from the upper plasma region during an second SQNB procedure; a first gas injection system coupled to the plasma generation chamber that is configured to introduce the first plasma generation gas to the upper plasma region during a first SQNB procedure and is further configured to introduce the second plasma generation gas to the upper plasma region during an second SQNB procedure; a separation member disposed between the upper plasma region and the switchable plasma region, the separation member includes one or more “beam creation” openings that are configured to allow a first electron flux from the upper plasma region to the switchable plasma region to form a first switchable plasma at a first switchable plasma potential and are further configured to allow a second electron flux from the upper plasma region to the switchable plasma region to form a second switchable plasma at a second switchable plasma potential; a lower bias electrode coupled to the SQNB process chamber that is configured to elevate the first switchable plasma potential above the first upper plasma potential in order to control the first electron flux in a plurality of beams during the first SQNB procedure and is further configured to elevate the second switchable plasma potential above the second upper plasma potential in order to control the second electron flux in the plurality of beams during the second SQNB procedure; a switchable substrate holder coupled to the SQNB process chamber and configured to support the substrate proximate the switchable plasma region; the switchable substrate holder being coupled to a multi-position switch that is configured to be in a first position during a first SQNB procedure and to be in a second position during an second SQNB procedure; and a vacuum pumping system coupled to the SQNB process chamber and configured to pump the switchable plasma region in the SQNB process chamber. For example, the first and/or second switchable plasma can be established during masking layer curing, drying, shrinking, correcting, and/or hardening procedures, etch procedures, ashing procedures, cleaning procedures, or deposition procedures, or any combination thereof.

According to another embodiment, a method for processing a patterned substrate is described that comprises: disposing the patterned substrate in a switchable process chamber configured to modify a masking layer on the patterned substrate; forming a first upper plasma in a upper plasma region at a first upper plasma potential; forming a first switchable (modifying) plasma in a switchable plasma region at a first switchable plasma potential using first electron flux in a plurality of beams from the upper plasma region; elevating the first switchable plasma potential above the first upper plasma potential to control the first electron flux; controlling a first pressure in the switchable process chamber; and exposing the substrate to the first switchable (modifying) plasma; forming a second upper plasma in a upper plasma region at a second upper plasma potential; forming a second switchable (feature-forming) plasma in the switchable plasma region at a second switchable plasma potential using a second electron flux in the plurality of beams from the upper plasma region; elevating the second switchable plasma potential above the second upper plasma potential to control the second electron flux; controlling a second pressure in the switchable process chamber; and exposing the substrate to the second switchable (feature-forming) plasma.

The invention can provide apparatus and methods of processing a substrate in real-time using subsystems and processing sequences created to modify radiation-sensitive materials. In addition, the modified radiation-sensitive layer can be used in a second SQNB procedure to more accurately control gate and/or spacer critical dimensions (CDs), to control gate and/or spacer CD uniformity, and to eliminate line edge roughness (LER) and line width roughness (LWR).

Other aspects of the invention will be made apparent from the description that follows and from the drawings appended hereto.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 shows an exemplary block diagram of a processing system in accordance with embodiments of the invention;

FIG. 2A shows a simplified view of a switchable quasi-neutral beam (SQNB) subsystem in accordance with embodiments of the invention;

FIG. 2B illustrates exemplary conditions for first and/or second SQNB procedures to be performed in the switchable quasi-neutral beam (SQNB) subsystem depicted in FIG. 2A in accordance with embodiments of the invention;

FIG. 3 shows an exemplary block diagram of another switchable quasi-neutral beam (SQNB) processing system in accordance with embodiments of the invention;

FIG. 4 shows an exemplary flow diagram of a method for processing substrates using a switchable quasi-neutral beam (SQNB) system in accordance with embodiments of the invention; and

FIG. 5A and FIG. 5B illustrate exemplary views of a procedure for processing a metal gate structure using a switchable quasi-neutral beam (SQNB) system in accordance with embodiments of the invention.

### DETAILED DESCRIPTION

The invention provides apparatus and methods of processing a substrate in real-time using switchable quasi-neutral beam (SQNB) subsystems and SQNB processing sequences created to modify radiation-sensitive materials. In addition, the modified radiation-sensitive layer can be used to more accurately control gate and/or spacer critical dimensions (CDs), to control gate and/or spacer CD uniformity, and to eliminate line edge roughness (LER) and line width roughness (LWR). For example, the SQNB subsystems and SQNB processing sequences can be used to alter the mechanical properties of the masking layer materials, can be used to modify the chemical and/or mechanical properties of the masking layer materials, and can be used to alter the etch resistance of the masking layer materials.

In some embodiments, apparatus and methods are provided for creating and/or using a metrology library that includes profile data and diffraction signal data for modified photoresist features and periodic structures created during first SQNB procedures. In addition, the metrology library can include profile data and diffraction signal data for new features created using the modified photoresist features and periodic structures in additional SQNB procedures.

One or more evaluation features can be provided at various locations on a substrate and can be used to evaluate and/or verify SQNB procedures and associated models. Substrates can have real-time and historical data associated with them, and the substrate data can include SQNB data. In addition, the substrate can have other data associated with them, and the other data can include gate structure data, the number of required sites, the number of visited sites, confidence data and/or risk data for one or more of the sites, site ranking data, transferring sequence data, or process-related data, or evaluation/verification-related data, or any combination thereof. The data associated with substrates can include transfer sequence data that can be used to establish when and where to transfer the substrates, and transfer sequences can be changed using operational state data.

As feature sizes decrease below the 45 nm technology node, accurate processing and/or measurement data becomes more important and more difficult to obtain. SQNB procedures can be used to more accurately process and/or measure these ultra-small devices and features. The data from a SQNB procedure can be compared with the warning and/or control limits. When a run-rule is violated, an alarm can be generated indicating a processing problem, and correction procedures can be performed in real time.

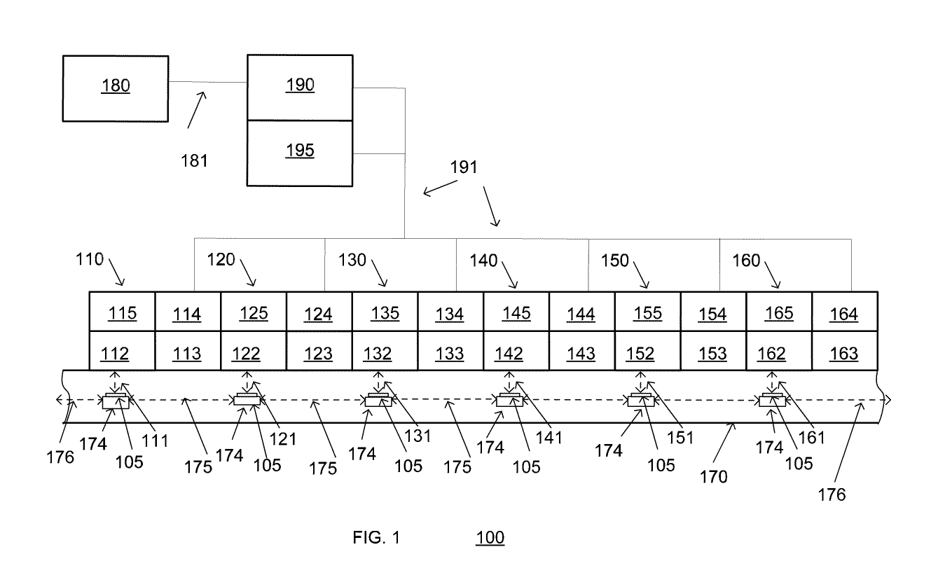

FIG. 1 shows an exemplary block diagram of a processing system in accordance with embodiments of the invention. In the illustrated embodiment, processing system 100 comprises a lithography subsystem 110, an exposure subsystem 120, an etch subsystem 130, a deposition subsystem 140, a SQNB subsystem 150, an evaluation subsystem 160, a transfer subsystem 170, a manufacturing execution system (MES) 180, a system controller 190, and a memory/database 195. Single subsystems (110, 120, 130, 140, 150, 160, and 170) are shown in the illustrated embodiment, but this is not required for the invention. In some embodiments, multiple subsystems (110, 120, 130, 140, 150, 160, and 170) can be used in a processing system 100. In addition, one or more of the subsystems (110, 120, 130, 140, 150, 160, and 170) can comprise one or more processing elements that can be used in SQNB processing sequences and associated models. Alternatively, a switchable neutral beam (SNB) subsystem and/or SNB processing sequences may be used.

The system controller 190 can be coupled to the lithography subsystem 110, the exposure subsystem 120, the etch subsystem 130, the deposition subsystem 140, the SQNB subsystem 150, the evaluation subsystem 160, and the transfer subsystem 170 using a data transfer subsystem 191. The system controller 190 can be coupled to the MES 180 using the first data transfer subsystem 181. Alternatively, other configurations may be used. For example, the etch subsystem 130, the deposition subsystem 140, the SQNB subsystem 150, the evaluation subsystem 160, and a portion of the transfer subsystem 170 can be subsystems available from Tokyo Electron Limited.

The lithography subsystem 110 can comprise one or more transfer/storage elements 112, one or more processing elements 113, one or more controllers 114, and one or more evaluation elements 115. One or more of the transfer/storage elements 112 can be coupled to one or more of the processing elements 113 and/or to one or more of the evaluation elements 115 and can be coupled to the transfer subsystem 170 using one or more transfer devices 111. One or more substrates 105 can be transferred between the transfer subsystem 170 and the lithography subsystem 110 in real time using one or more of the transfer devices 111. For example, the transfer subsystem 170 can be coupled to one or more of the transfer/storage elements 112, to one or more of the processing elements 113, and/or to one or more of the evaluation elements 115. One or more of the controllers 114 can be coupled to one or more of the transfer/storage elements 112, to the one or more of the processing elements 113, and/or to one or more of the evaluation elements 115.

In some embodiments, the lithography subsystem 110 can perform coating procedures, thermal procedures, measurement procedures, inspection procedures, alignment procedures, and/or storage procedures on one or more substrates. For example, one or more lithography-related processes can be used to deposit one or more masking layers that can include photoresist material, and/or anti-reflective coating (ARC) material, and can be used to thermally process (bake) one or more of the masking layers. In addition, lithography subsystem 110 can be used to develop, measure, and/or inspect one or more of the patterned masking layers on one or more of the substrates.

The exposure subsystem 120 can comprise one or more transfer/storage elements 122, one or more processing elements 123, one or more controllers 124, and one or more evaluation elements 125. One or more of the transfer/storage elements 122 can be coupled to one or more of the processing elements 123 and/or to one or more of the evaluation elements 125 and can be coupled to the transfer subsystem 170 using one or more transfer devices 121. One or more substrates 105 can be transferred between the transfer subsystem 170 and the exposure subsystem 120 in real time using one or more of the transfer devices 121. For example, the transfer subsystem 170 can be coupled to one or more of the transfer/storage elements 122, to one or more of the processing elements 123, and/or to one or more of the evaluation elements 125. One or more of the controllers 124 can be coupled to one or more of the transfer/storage elements 122, to the one or more of the processing elements 123, and/or to one or more of the evaluation elements 125.

In some embodiments, the exposure subsystem 120 can be used to perform wet and/or dry exposure procedures, and in other cases, the exposure subsystem 120 can be used to perform extreme ultraviolet (EUV) exposure procedures.

The etch subsystem 130 can comprise one or more transfer/storage elements 132, one or more processing elements 133, one or more controllers 134, and one or more evaluation elements 135. One or more of the transfer/storage elements 132 can be coupled to one or more of the processing elements 133 and/or to one or more of the evaluation elements 135 and can be coupled to the transfer subsystem 170 using one or more transfer devices 131. One or more substrates 105 can be transferred between the transfer subsystem 170 and the etch subsystem 130 in real time using one or more of the transfer devices 131. For example, the transfer subsystem 170 can be coupled to one or more of the transfer/storage elements 132, to one or more of the processing elements 133, and/or to one or more of the evaluation elements 135. One or more of the controllers 134 can be coupled to one or more of the transfer/storage elements 132, to the one or more of the processing elements 133, and/or to one or more of the evaluation elements 135. For example, one or more of the processing elements 133 can be used to perform plasma or non-plasma etching, ashing, and cleaning procedures, or plasma or non-plasma etching procedures. Evaluation procedures and/or inspection procedures can be used to measure and/or inspect one or more surfaces and/or layers of the substrates.

The deposition subsystem 140 can comprise one or more transfer/storage elements 142, one or more processing elements 143, one or more controllers 144, and one or more evaluation elements 145. One or more of the transfer/storage elements 142 can be coupled to one or more of the processing elements 143 and/or to one or more of the evaluation elements 145 and can be coupled to the transfer subsystem 170 using one or more transfer devices 141. One or more substrates 105 can be transferred between the transfer subsystem 170 and the deposition subsystem 140 in real time using one or more of the transfer devices 141. For example, the transfer subsystem 170 can be coupled to one or more of the transfer/storage elements 142, to one or more of the processing elements 143, and/or to one or more of the evaluation elements 145. One or more of the controllers 144 can be coupled to one or more of the transfer/storage elements 142, to the one or more of the processing elements 143, and/or to one or more of the evaluation elements 145. For example, one or more of the processing elements 143 can be used to perform physical vapor deposition (PVD) procedures, chemical vapor deposition (CVD) procedures, ionized physical vapor deposition (iPVD) procedures, atomic layer deposition (ALD) procedures, plasma enhanced atomic layer deposition (PEALD) procedures, and/or plasma enhanced chemical vapor deposition (PECVD) procedures. Evaluation procedures and/or inspection procedures can be used to measure and/or inspect one or more surfaces of the substrates.

The SQNB subsystem 150 can comprise one or more transfer/storage elements 152, one or more switchable processing elements 153, one or more controllers 154, and one or more switchable evaluation elements 155. For example, one or more of the switchable evaluation elements 155 can perform real-time measurement, inspection, and/or verification procedures during SQNB processing sequences. One or more of the transfer/storage elements 152 can be coupled to one or more of the switchable processing elements 153 and/or to one or more of the switchable evaluation elements 155 and can be coupled to the transfer subsystem 170 using one or more transfer devices 151. One or more substrates 105 can be transferred between the transfer subsystem 170 and the SQNB subsystem 150 in real time using one or more of the transfer devices 111. For example, the transfer subsystem 170 can be coupled to one or more of the transfer/storage elements 152, to one or more of the switchable processing elements 153, and/or to one or more of the switchable evaluation elements 155. One or more of the controllers 154 can be coupled to one or more of the transfer/storage elements 152, to the one or more of the switchable processing elements 153, and/or to one or more of the switchable evaluation elements 155.

The evaluation subsystem 160 can comprise one or more transfer/storage elements 162, one or more measuring elements 163, one or more controllers 164, and one or more inspection elements 165. One or more of the transfer/storage elements 162 can be coupled to one or more of the measuring elements 163 and/or to one or more of the inspection elements 165 and can be coupled to the transfer subsystem 170 using one or more transfer devices 161. One or more substrates 105 can be transferred between the transfer subsystem 170 and the evaluation subsystem 160 in real time using one or more transfer devices 161. For example, the transfer subsystem 170 can be coupled to one or more of the transfer/storage elements 162, to one or more of the measuring elements 163, and/or to one or more of the inspection elements 165. One or more of the controllers 164 can be coupled to one or more of the transfer/storage elements 162, to the one or more of the measuring elements 163, and/or to one or more of the inspection elements 165. The evaluation subsystem 160 can comprise one or more measuring elements 163 that can be used to perform real-time optical evaluation procedures that can be used to measure target structures at one or more sites on a substrate using library-based or regression-based techniques. For example, the sites on substrate can include SQNB-related sites, target sites, overlay sites, alignment sites, measurement sites, verification sites, inspection sites, or damage-assessment sites, or any combination thereof. For example, one or more “golden substrates” or reference chips can be stored and used periodically to verify the performance of one or more of the measuring elements 163, and/or one or more of the inspection elements 165.

In some embodiments, the evaluation subsystem 160 can include an integrated Optical Digital Profilometry (iODP) elements (not shown), and iODP elements/systems are available from Timbre Technologies Inc. (a TEL company). Alternatively, other metrology systems and/or inspection systems may be used. For example, iODP techniques can be used to obtain real-time data that can include critical dimension (CD) data, gate structure data, and thickness data, and the wavelength ranges for the iODP data can range from less than approximately 200 nm to greater than approximately 900 nm. Exemplary iODP elements can include ODP Profiler Library elements, Profiler Application Server (PAS) elements, and ODP Profiler Software elements. The ODP Profiler Library elements can comprise application specific database elements of optical spectra and its corresponding semiconductor profiles, CDs, and film thicknesses. The PAS elements can comprise at least one computer that connects with optical hardware and computer network. The PAS elements can be configured to provide the data communication, ODP library operation, measurement process, results generation, results analysis, and results output. The ODP Profiler Software elements can include the software installed on PAS elements to manage measurement recipe, ODP Profiler library elements, ODP Profiler data, ODP Profiler search/match results, ODP Profiler calculation/analysis results, data communication, and PAS interface to various metrology elements and computer network.

The evaluation subsystem 160 can use polarizing reflectometry, spectroscopic ellipsometry, reflectometry, or other optical measurement techniques to measure accurate device profiles, accurate CDs, and multiple layer film thickness of a substrate. The integrated metrology process (iODP) can be executed as an integrated process in an integrated group of subsystems. In addition, the integrated process eliminates the need to break the substrate for performing the analyses or waiting for long periods for data from external systems. iODP techniques can be used with the existing thin film metrology systems for inline profile and CD measurement, and can be integrated with TEL processing systems and/or lithography systems to provide real-time process monitoring and control. Simulated metrology data can be generated by applying Maxwell's equations and using a numerical analysis technique to solve Maxwell's equations.

The transfer subsystem 170 can comprise transfer elements 174 coupled to transfer tracks (175 and 176) that can be used to receive substrates, transfer substrates, align substrates, store substrates, and/or delay substrates. For example, the transfer elements 174 can support two or more substrates. Alternatively, other transferring means may be used. The transfer subsystem 170 can load, transfer, store, and/or unload substrates based on a SQNB procedure, a SQNB processing sequence, a transfer sequence, operational states, the substrate and/or processing states, the processing time, the current time, the substrate data, the number of sites on the substrate, the type of sites on the substrates, the number of required sites, the number of completed sites, the number of remaining sites, or confidence data, or any combination thereof.

In some examples, transfer subsystem 170 can use loading data to determine where and when to transfer a substrate. In other examples, a transfer system can use SQNB processing data to determine where and when to transfer a substrate. Alternatively, other procedures may be used. For example, when the first number of substrates is less than or equal to the first number of available processing elements, the first number of substrates can be transferred to the first number of available processing elements in the one or more of the subsystems using the transfer subsystem 170. When the first number of substrates is greater than the first number of available processing elements, some of the substrates can be stored and/or delayed using one or more of the transfer/storage elements (112, 122, 132, 142, 152, and 162) and/or the transfer subsystem 170.

In addition, the one or more subsystems (110, 120, 130, 140, 150, 160, and 170) can be used when performing lithography-related procedures, exposure-related procedures, inspection-related procedures, measurement-related procedures, evaluation-related procedures, etch-related procedures, deposition-related procedures, thermal processing procedures, coating-related procedures, alignment-related procedures, polishing-related procedures, storage-related procedures, transfer procedures, cleaning-related procedures, rework-related procedures, oxidation-related procedures, nitridation-related procedures, or external processing elements, or any combination thereof.

Operational state data can be established for the subsystems (110, 120, 130, 140, 150, 160, and 170) and can be used and/or updated by the SQNB procedures. In addition, operational state data can be established for the transfer/storage elements (112, 122, 132, 142, 152, and 162), elements (113, 123, 133, 143, 153, and 163), and evaluation elements (115, 125, 135, 145, 155, and 165), and can be updated by SQNB procedures. For example, the operational state data for the processing elements can include availability data, matching data for the processing elements, expected processing times for some process steps and/or sites, yield data, confidence data and/or risk data for the processing elements, or confidence data and/or risk data for one or more first SQNB and/or second SQNB procedures. Updated operational states can be obtained by querying in real-time one or more processing elements, and/or one or more subsystems. Updated loading data can be obtained by querying in real-time one or more transfer elements, and/or one or more transfer subsystems.

One or more of the controllers (114, 124, 134, 144, 154, and 164) can be coupled to the system controller 190 and/or to each other using a data transfer subsystem 191. Alternatively, other coupling configurations may be used. The controllers can be coupled in series and/or in parallel and can have one or more input ports and/or one or more output ports. For example, the controllers may include microprocessors having one or more core processing elements.

In addition, subsystems (110, 120, 130, 140, 150, 160, and 170) can be coupled to each other and to other devices using intranet, internet, wired, and/or wireless connections. The controllers (114, 124, 134, 144, and 190) can be coupled to external devices as required.

One or more of the controllers (114, 124, 134, 144, 154, 164, and 190) can be used when performing real-time SQNB procedures. A controller can receive real-time data from a SQNB model to update subsystem, processing element, process, recipe, profile, image, pattern, simulation, sequence data, and/or model data. One or more of the controllers (114, 124, 134, 144, 154, 164, and 190) can be used to exchange one or more Semiconductor Equipment Communications Standard (SECS) messages with the Manufacturing Execution Systems (MES) 180 or other systems (not shown), read and/or remove information, feed forward, and/or feedback the information, and/or send information as a SECS message. One or more of the formatted messages can be exchanged between controllers, and the controllers can process messages and extract new data in real-time. When new data is available, the new data can be used in real-time to update a model and/or procedure currently being used for the substrate and/or lot. For example, the current layout can be examined using the updated model and/or procedure when the model and/or procedure can be updated before the current layout is examined. The current layout can be examined using a non-updated model and/or procedure when an update cannot be performed before the current layout is processed. In addition, formatted messages can be used when resists are changed, when resist models are changed, when processing sequences are changed, when design rules are changed, or when layouts are changed.

In some examples, the MES 180 may be configured to monitor some subsystem and/or system processes in real-time, and factory level intervention and/or judgment rules can be used to determine which processes are monitored and which data can be used. For example, factory level intervention and/or judgment rules can be used to determine how to manage the data when an error condition occurs in a SQNB procedure. The MES 180 can also provide modeling data, processing sequence data, and/or substrate data.

In addition, controllers (114, 124, 134, 144, 154, 164, and 190) can include memory (not shown) as required. For example, the memory (not shown) can be used for storing information and instructions to be executed by the controllers, and may be used for storing temporary variables or other intermediate information during the execution of instructions by the various computers/processors in the processing system 100. One or more of the controllers (114, 124, 134, 144, 154, 164, and 190), or other system components can comprise the means for reading data and/or instructions from a computer readable medium and can comprise the means for writing data and/or instructions to a computer readable medium.

The processing system 100 can perform a portion of or all of the processing steps of the invention in response to the computers/processors in the processing system executing one or more sequences of one or more instructions contained in a memory and/or received in a message. Such instructions may be received from another computer, a computer readable medium, or a network connection.

In some embodiments, an integrated system can be configured using system components from Tokyo Electron Limited (TEL), and external subsystems and/or tools may be included. For example, measurement elements can be provided that can include a CD-Scanning Electron Microscopy (CDSEM) system, a Transmission Electron Microscopy (TEM) system, a focused ion beam (FIB) system, an Optical Digital Profilometry (ODP) system, an Atomic Force Microscope (AFM) system, or another inspection system. The subsystems and/or processing elements can have different interface requirements, and the controllers can be configured to satisfy these different interface requirements.

One or more of the subsystems (110, 120, 130, 140, 150, 160, and 170) can perform control applications, Graphical User Interface (GUI) applications, and/or database applications. In addition, one or more of the subsystems (110, 120, 130, 140, 150, 160, and 170) and/or controllers (114, 124, 134, 144, 154, 164, and 190) can include Design of Experiment (DOE) applications, Advanced Process Control (APC) applications, Fault Detection and Classification (FDC) applications, and/or Run-to-Run (R2R) applications.

Output data and/or messages from SQNB procedures can be used in subsequent procedures to optimize the process accuracy and precision. Data can be passed to SQNB procedures in real-time as real-time variable parameters, overriding current model values, and reducing DOE tables. Real-time data can be used with a library-based system, or regression-based system, or any combination thereof to optimize a P—H procedure.

When a library-based process is used, some of the data in the library can be generated and/or enhanced using SQNB procedures, recipes, profiles, and/or models. For example, a library can comprise simulated and/or measured data for SQNB procedures and corresponding sets of profile data. The library-based processes can be performed in real-time. An alternative procedure for generating SQNB data for a library can include using a machine learning system (MLS). For example, prior to generating the library data, the MLS can be trained using known input and output data, and the MLS may be trained with a subset of the SQNB data.

SQNB procedures can include intervention and/or judgment rules that can be executed whenever a matching context is encountered. Intervention and/or judgment rules and/or limits can be established based on historical procedures, on the customer's experience, or process knowledge, or obtained from a host computer. Rules can be used in Fault Detection and Classification (FDC) procedures to determine how to respond to alarm conditions, error conditions, fault conditions, and/or warning conditions. The rule-based FDC procedures can prioritize and/or classify faults, predict system performance, predict preventative maintenance schedules, decrease maintenance downtime, and extend the service life of consumable parts in the system. Various actions can take place in response to an alarm/fault, and the actions taken on the alarm/fault can be context-based, and the context data can be specified by a rule, a system/process recipe, a chamber type, identification number, load port number, cassette number, lot number, control job ID, process job ID, slot number and/or the type of data.

Unsuccessful SQNB procedures can report a failure when a limit is exceeded, and successful procedures can create warning messages when limits are being approached. Pre-specified failure actions for procedures errors can be stored in a database, and can be retrieved from the database when an error occurs. For example, SQNB procedures can reject the data at one or more of the sites for a substrate when a measurement procedure fails.

SQNB procedures can be used to create, modify, and/or evaluate isolated and/or nested structures at different times and/or sites. For example, gate stack dimensions and substrate thickness data can be different near isolated and/or nested structures, and gate stack dimensions and substrate thickness data can be different near open areas and/or trench array areas. The modified photoresist features created by the SQNB procedure can subsequently be used to create optimized features and/or structures for etched isolated and/or nested structures.

The SQNB procedures can be used to reinforce the photo-resist film, supply optimum polymers, and suppress dissociation of the gases used during some of the various SQNB procedures. Therefore, the surface roughness of the photo-resist can be decreased. Further, the CD of an opening portion formed in the photo-resist film can be prevented from expanding, thereby realizing pattern formation with high accuracy. Particularly, these effects are more enhanced by controlling the DC voltage to suitably exercise the three functions described herein, i.e., the etching function, the plasma optimizing function, and the electron supply function.

The amount of by-products deposited during a SQNB procedure depends on the potential difference between the plasma and the DC electrode, chamber wall, or the like. Accordingly, deposition of by-products can be suppressed by controlling the plasma potential, and the voltage applied from the multi-output supply system to the DC electrode can be controlled to lower the plasma potential. The plasma potential Vₚ is preferably set at a value within a range of negative 100 to negative 3000 volts.

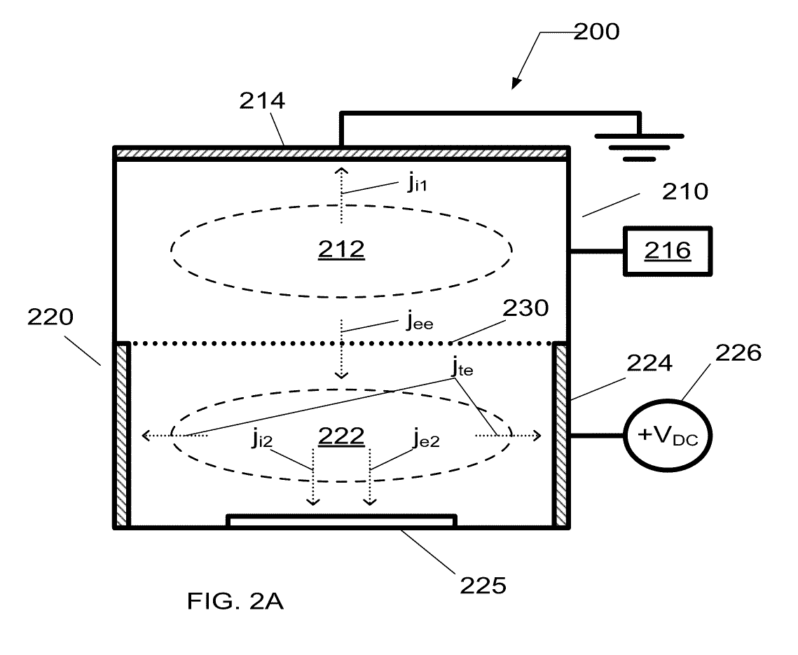

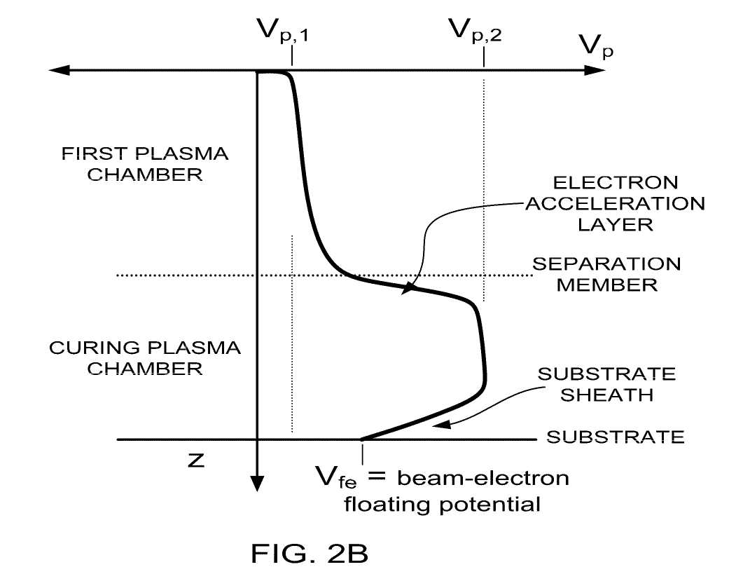

FIG. 2A shows a simplified view of a SQNB subsystem in accordance with embodiments of the invention. In the illustrated embodiment shown in FIG. 2A, a SQNB subsystem 200 is described that is configured to perform a first SQNB procedure and/or a second SQNB procedure using an un-patterned and/or a patterned photoresist layer on a substrate with space-charge neutralized beam that can be activated during a first SQNB procedure and/or a second SQNB procedure.

FIG. 2B illustrates exemplary conditions when the first SQNB and/or second SQNB procedures are performed in the SQNB subsystem depicted in FIG. 2A. A beam-electron floating potential (V_{fe}) is shown that exists because somewhere in the plasma there are insulator surfaces that are not under beam-electron bombardment; instead, these surfaces are under a Maxwellian thermal electron flux. The floating potential of these surfaces are the “thermal Maxwellian floating potential”.

As illustrated in FIGS. 2A and 2B, the SQNB subsystem 200 can comprise a upper plasma chamber 210 for forming a upper plasma 212 at a upper plasma potential (Vₚ₁), and a switchable plasma chamber 220 for forming a switchable plasma 222 at a switchable plasma potential (Vₚ₂) greater than the upper plasma potential (Vₚ₁). The upper plasma 212 can be formed by coupling power, such as radio frequency (RF) power, to an ionizable gas in the upper plasma chamber 210, while the switchable plasma 222 is formed using electron flux (e.g., energetic electron (ee) current, (jₑₑ) from the upper plasma 212. The power ranges from approximately 10 watts to approximately 700 watts. Further, the switchable plasma chamber 220 comprises a switchable substrate holder configured to position a substrate 225 at direct current (DC) ground or floating ground in the switchable plasma chamber 220 to be exposed to the switchable plasma 222 at the switchable plasma potential.

The upper plasma chamber 210 comprises a plasma generation system 216 configured to ignite and heat the upper plasma 212. The upper plasma 212 may be heated by any conventional plasma generation system including, but not limited to, an inductively coupled plasma (ICP) source, a transformer coupled plasma (TCP) source, a capacitively coupled plasma (CCP) source, an electron cyclotron resonance (ECR) source, a helicon wave source, a surface wave plasma source, a surface wave plasma source having a slotted plane antenna, etc. Although the upper plasma 212 may be heated by any plasma source, it is desired that the upper plasma 212 be heated by a method that produces a reduced or minimum fluctuation in its plasma potential (Vₚ₁). For example, an ICP source is a practical technique that produces a reduced or minimum (Vₚ₁) fluctuation.

Additionally, the upper plasma chamber 210 comprises a direct current (DC) conductive ground electrode 214 having a conductive surface that acts as a boundary in contact with the upper plasma 212. The DC conductive ground electrode 214 is coupled to DC ground. The DC conductive ground electrode 214 acts as an ion sink that is driven by the upper plasma 212 at the upper plasma potential (Vₚ₁). Although one DC conductive ground electrode 214 is shown in FIG. 2A, the SQNB subsystem 200 may comprise one or more DC conductive ground electrodes.

Although not necessary, it is desirable that the DC conductive ground electrode 214 comprises a relatively large area in contact with the upper plasma 212. The larger the area at DC ground, the lower the upper plasma potential. For example, the surface area of the conductive surface for the DC conductive ground electrode 214 in contact with the upper plasma 212 may be greater than any other surface area in contact with the upper plasma 212. Additionally, for example, the surface area of the conductive surface for the DC conductive ground electrode 214 in contact with the upper plasma 212 may be greater than the total sum of all other conductive surfaces that are in contact with the upper plasma 212. Alternatively, as an example, the conductive surface for the DC conductive ground electrode 214 in contact with the upper plasma 212 may be the only conductive surface that is in contact with the upper plasma 212. The DC conductive ground electrode 214 may offer the lowest impedance path to ground.

As described above, (energetic) electron flux (or electron current jₑₑ) from the upper plasma 212 initiates and sustains the switchable plasma 222 in the switchable plasma chamber 220. In order to control the electron flux and produce a mono-energetic space-charge neutralized neutral beam, the upper plasma potential (Vₚ₁), as described above, and the switchable plasma potential (Vₚ₂) should be stable with substantially reduced or minimal fluctuations if any fluctuations at all. To achieve this stability in the switchable plasma 222, the switchable plasma chamber 220 comprises a DC conductive bias electrode 224 having a conductive surface in contact with the switchable plasma 222, wherein the DC conductive bias electrode 224 is coupled to a DC voltage source 226. The DC voltage source 226 is configured to bias the DC conductive bias electrode 224 at a positive DC voltage (+V_{DC}). As a result, the switchable plasma potential (Vₚ₂) is a boundary-driven plasma potential driven by a (+V_{DC}) voltage source, thus causing (Vₚ₂) to rise to about (+V_{DC}) and remain substantially stable. Although one DC conductive bias electrode 224 is shown in FIG. 2A, the SQNB subsystem 200 may comprise one or more DC conductive bias electrodes.

Furthermore, the SQNB subsystem 200 comprises a separation member 230 disposed between the upper plasma chamber 210 and the switchable plasma chamber 220. The separation member 230 may act as an electron diffuser. The electron diffusion is driven by an electric field through an electron acceleration layer created by the potential difference ΔV={(Vₚ₂)−(Vₚ₁)}. The separation member 230 may comprise an insulator, such as quartz or alumina, or the separation member 230 may comprise a dielectric coated conductive material that is electrically floating and has high RF impedance to ground. Due to the large electric field across the electron acceleration layer V̅z={(Vₚ₂)−(Vₚ₁)}, the electron flux is sufficiently energetic to sustain ionization in the switchable plasma 222. However, the SQNB subsystem 200 may optionally comprise a plasma heating system configured to further heat the switchable plasma 222.

The separation member 230 may comprise one or more openings to permit the passage of the energetic electron flux from the upper plasma chamber 210 to the switchable plasma chamber 220. The total area of the one or more openings can be adjusted relative to the surface area of the DC conductive ground electrode 214 to ensure a relatively large potential difference ΔV={(Vₚ₂)−(Vₚ₁)} while minimizing reverse ion current from the switchable plasma 222 to the upper plasma 212, and thereby ensure a sufficient ion energy for ions striking the substrate 225.

As illustrated in FIG. 2A, a first ion flux (e.g., ion current, jᵢ₁) from a first population of ions in the upper plasma 212 flows to the DC conductive ground electrode 214 in the upper plasma chamber 210 in a quantity approximately equivalent to the energetic electron flux (or electron current jₑₑ) from the upper plasma 212 through the electron acceleration layer at the separation member 230 into the switchable plasma 222, i.e., |jᵢ₁|˜|jₑₑ|.

As described above, the energetic electron flux is sufficiently energetic to form the switchable plasma 222. Therein, a population of thermal electrons and a second population of ions are formed. The thermal electrons are largely a result of ejected electrons upon ionization of the switchable plasma 222 by the incoming energetic electron flux (or electron current jₑₑ). However, some energetic electrons from the energetic electron flux may lose a sufficient amount of energy and, thus, become part of the thermal electron population.

Due to Debye shielding, only the thermal electrons of the switchable plasma 222 flow to the DC conductive bias electrode 224 (e.g., thermal electron current, jₜₑ) in a quantity approximately equal to the energetic electron flux, i.e., |jₜₑ|˜|jₑₑ|. While thermal electron current jₜₑ is directed to the DC conductive bias electrode 224, a second ion flux from the second population of ions is directed to the substrate at (Vₚ₂) (as ion current, ji₂;) which is approximately equivalent to the sum of the energetic current to the substrate 225, jₑₑ, and the energetic electron generated secondary electron current (jₑₛₑ).

If the incoming energetic electron energy is sufficiently high, a substantial fraction of the energetic electron flux (jₑₑ) will survive the passage through the switchable plasma 222 and strike substrate (wafer) 225. However, regardless of their origin (i.e., energetic electrons from energetic electron flux jₑₑ or energetic electrons from the thermal electron population), only energetic electrons capable of passing through the substrate sheath (i.e. climbing the potential “hill”, or {(V_{fe})−(Vₚ₁)}, wherein (V_{fe}) is the energetic electron floating potential) will reach substrate 225. Since substrate 225 is at floating DC ground, the ion current jᵢ₂ that is fed by the second ion population in the switchable plasma 222 (having ion energy characterized by {(Vₚ₂)−(V_{fe})} will be equivalent to the electron current jₑ₂ (i.e., no net current, or |jᵢ₂|˜|jₑ₂| Or jᵢ₂+jₑ₂˜jᵢ₂+jₑₑ+jₑₛₑ˜0). Alternatively, the substrate 225 may be at approximately DC ground since the floating-ground surface potential is expected to be slightly above DC ground.

In such a configuration for the SQNB subsystem 200, the elevation of the switchable plasma potential above the upper plasma potential drives an energetic electron beam (having electron current jₑₑ) to form the switchable plasma 222, while particle balance throughout the SQNB subsystem 200 enforces an equal number of electrons (e.g., electron current, jₑ₂) and ions (e.g., ion current, jᵢ₂) striking substrate 225 (i.e., |jᵢ₂|˜|jₑ₂|). This charge balance manifests as a space-charge neutralized neutral beam directed to substrate 225 that can activate a first SQNB procedure and/or a second SQNB procedure at the substrate 225.

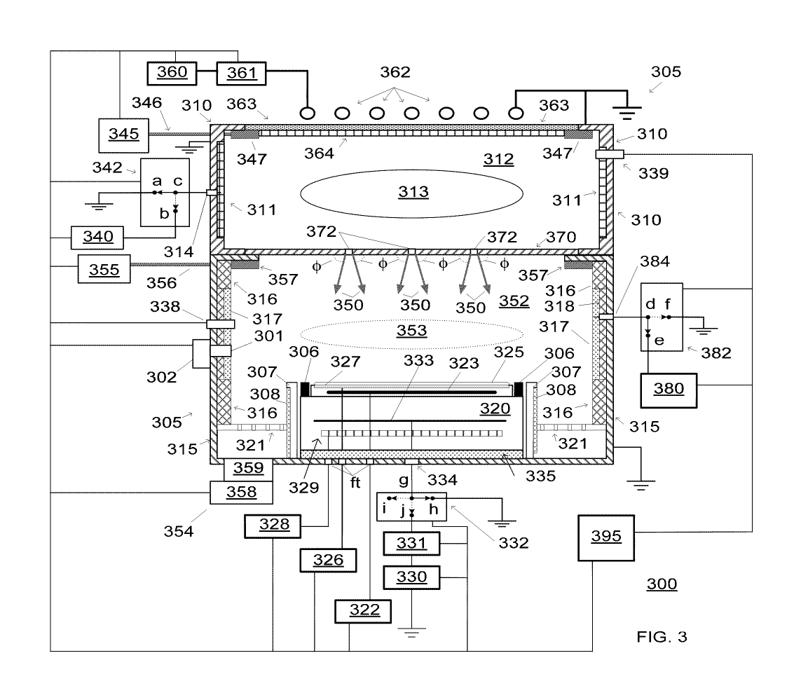

FIG. 3 shows an exemplary block diagram of a switchable neutral beam subsystem in accordance with embodiments of the invention. In the illustrated embodiment, an exemplary Switchable Quasi-Neutral Beam (SQNB) system is shown, and the exemplary SQNB system 300 can comprise a Switchable Quasi-Neutral Beam (SQNB) subsystem 305 that can include at least one plasma generation chamber 310 and at least one SQNB process chamber 315. One or more of the plasma generation chambers 310 can be configured to produce an upper plasma 313 at an upper plasma potential, and at least one of the SQNB process chambers 315 can be configured to provide a contaminant-free, vacuum environment for performing a first SQNB procedure during a first SQNB time and for performing a second SQNB procedure during a second SQNB time using a patterned substrate 325. For example, the first and/or second SQNB procedures can include masking layer curing, drying, shrinking, correcting, and/or hardening procedures, etch procedures, ashing procedures, cleaning procedures, or deposition procedures, or any combination thereof. Alternatively, a neutral beam (NB) subsystem or a switchable neutral beam (SNB) system may be used.

The plasma generation chamber 310 can include an upper plasma region 312 that can be configured to receive a first plasma generation gas at a first flow rate and can be configure to form upper plasma 313. The SQNB process chamber 315 can include a switchable plasma region 352 disposed downstream of the upper plasma region 312. The SQNB process chamber 315 can be configured to receive electron flux and one or more plasma species from the upper plasma region 312 and form switchable plasma 353 therein at a switchable plasma potential and a second pressure. In some examples, one or more separation members 370 can be configured between the upper plasma region 312 and the switchable plasma region 352.

The SQNB system 300 can include an upper gas supply system 345 that can be coupled to one or more first gas distribution elements 347 in the plasma generation chamber 310 using at least one first supply line 346. The first gas distribution elements 347 can be configured within the plasma generation chamber 310 and can be used to introduce the first plasma generation gas to one or more zones in the upper plasma region 312. One or more of the controllers 395 can be coupled to the upper gas supply system 345, and at least one of the controllers 395 can be configured to control and/or monitor the upper gas supply system 345. In addition, the first gas distribution elements 347 can be configured to provide different gasses at different flow rates to one or more of the zones in the upper plasma region 312. Alternatively, a different introduction method may be used. The first plasma generation gas can comprise an electropositive gas, or an electronegative gas, or a mixture thereof. For example, the first plasma generation gas may comprise a noble gas, an oxygen-containing gas, a nitrogen-containing gas, a fluorine-containing gas, or a carbon-containing gas, or any combination thereof. In additional examples, the first plasma generation gas can comprise any gas suitable for performing a SQNB procedure using the patterned substrate 325, and the first plasma generation gas can comprise any gas having chemical constituents, atomic or molecular, suitable for performing a SQNB procedure using the patterned substrate 325. These chemical constituents may comprise etchants, film-forming gases, dilutants, cleaning gases, etc. The upper gas supply system 345 can include one or more gas supplies or gas sources, one or more control valves, one or more filters, one or more mass flow controllers, one or more measurement devices, etc. The first supply line 346 and/or the first gas distribution elements 347 can include one or more control valves, one or more filters, one or more mass flow controllers, etc.

In addition, the exemplary SQNB system 300 can comprise a plasma generation source 360 that can be coupled to multi-turn inductive coil 362, and the plasma generation source 360 can comprise a radio frequency (RF) generator that couples RF power through a match network 361 to the multi-turn inductive coil 362. One or more of the controllers 395 can be coupled to the plasma generation source 360 and the match network 361, and at least one of the controllers 395 can be configured to control and/or monitor the plasma generation source 360 and the match network 361. For example, the RF power from the plasma generation source 360 can range from approximately 10 watts to approximately 700 watts. RF power is inductively coupled from the multi-turn inductive coil 362 through a dielectric window 363 to the upper plasma 313 in the upper plasma region 312. The match network 361 can be used to improve the transfer of RF power to plasma by reducing the reflected power, and can be used to measure transmitted and/or reflected power. Match network topologies (e.g. L-type, π-type, T-type, etc.) and automatic control methods are well known to those skilled in the art.

A typical frequency for the application of RF power to the multi-turn inductive coil 362 can range from about 2 MHz to about 100 MHz. In addition, a slotted Faraday shield 364 can be employed to reduce capacitive coupling between the multi-turn inductive coil 362 and plasma. Although the upper plasma 313 may be heated by any plasma source, it is desired that the upper plasma be heated by a method, which is shown in FIG. 2, that produces a minimum fluctuation in its plasma potential Vᵤₚ.

In alternate embodiments, a different plasma generation system (not shown) can be coupled to the plasma generation chamber 310 and configured to generate the upper plasma 313 in the upper plasma region 312. The different plasma generation system may include a system configured to produce a capacitively coupled plasma (CCP), an inductively coupled plasma (ICP), a transformer coupled plasma (TCP), a surface wave plasma, a helicon wave plasma, or an electron cyclotron resonant (ECR) heated plasma, or other type of plasma understood by one skilled in the art of plasma formation. In addition, any ICP source can be used that produces a reduced or minimum (Vₚ₁) fluctuation.

In some embodiments, the SQNB system 300 can include an upper power supply 340, an upper multi-position switch 342 that can be coupled to the upper power supply 340, and an upper feed-thru element 314. One or more of the controllers 395 can be coupled to the upper power supply 340 and the upper multi-position switch 342, and at least one of the controllers 395 can be configured to control and/or monitor the upper power supply 340 and the upper multi-position switch 342. For example, the upper feed-thru element 314 can include a filter and/or a sensor. The upper feed-thru element 314 can be used to couple a first common port (c) of the upper multi-position switch 342 to an upper direct current (DC) conductive electrode 311 in the plasma generation chamber 310, and upper feed-thru element 314 can be configured to allow electrical connection to the upper DC conductive electrode 311.

In addition, the upper multi-position switch 342 can include a common port (c), a first switchable port (a) that can be coupled to a ground potential, and a second switchable port (b) that can be coupled to the upper power supply 340. When the first position (path c-a) is used, the upper DC conductive electrode 311 can be coupled to the ground potential, and when the second position (path c-b) is used, the upper DC conductive electrode 311 can be coupled to the upper power supply 340. For example, the upper power supply 340 can provide DC power, and/or AC power, and the output from the upper power supply 340 can be constant, can be varied, can be pulsed, can be stepped, and/or can be ramped. In some examples, when the upper DC conductive electrode 311 is coupled to upper power supply 340, the upper power supply 340 can provide a DC voltage that is less than the bias DC voltage provided to the lower bias electrode 317.

In other embodiments, the upper DC conductive electrode 311 may be coupled to ground, and the upper feed-thru element 314, the upper power supply 340, and/or the upper multi-position switch 342 may not be required. In still other embodiments, the upper DC conductive electrode 311 may be coupled to ground using the upper power supply 340.

The upper DC conductive electrode 311 can have a conductive surface that acts as a boundary in contact with the upper plasma 313. For example, the upper DC conductive electrode 311 can comprise a doped silicon electrode. The upper DC conductive electrode 311 can act as an ion sink that is driven by the upper plasma 313 at the upper plasma potential (Vₚ₁). Although single elements are shown in FIG. 3, the SQNB system 300 may comprise one or more upper DC conductive electrodes 311, one or more upper power supplies, and one or more upper multi-position switches 342.

When the upper DC conductive electrode 311 is grounded, it is desirable that the upper DC conductive electrode 311 comprises a relatively large area in contact with the upper plasma 313. The upper plasma potential can be made lower by increasing the surface area of the upper DC conductive electrode 311 when it is coupled to a DC ground. For example, the surface area of the conductive surface for the upper DC conductive electrode 311 in contact with the upper plasma 313 may be greater than any other surface area in contact with the upper plasma 313. Additionally, for example, the surface area of the conductive surface for the upper DC conductive electrode 311 in contact with the upper plasma 313 may be greater than the total sum of all other conductive surfaces that are in contact with the upper plasma 313. Alternatively, as an example, the conductive surface for the upper DC conductive electrode 311 in contact with the upper plasma 313 may be the only conductive surface that is in contact with the upper plasma 313. The upper DC conductive electrode 311 may offer the lowest impedance path to DC ground.

In addition, the SQNB subsystem 305 can include at least one separation member 370 that can be configured between the upper plasma region 312 and the switchable plasma region 352. The separation member 370 can include one or more openings 372 that can be configured to create a plurality of beams 350 that can include at least one plasma species as well as an electron flux from the upper plasma 313 in the upper plasma region 312 to the switchable plasma region 352. For example, the electrons and/or ions in the plurality of beams 350 can be used to form the switchable plasma 353 in the switchable plasma region 352. For example, the separation member 370 can include a plurality of openings 372, and each of the openings 372 can be configured to create a beam 350 that can have a beam angle (φ). The beam angle (φ) can vary from approximately 80 degrees to approximately 89.5 degrees. In some examples, the beam angle can be defined using a probability distribution function of electron/particle angular trajectory.

One or more of the openings 372 in the separation member 370 can comprise a super-Debye length apertures, i.e., the transverse dimension or diameter is larger than the Debye length. The openings 372 can be sufficiently large to permit adequate electron transport, and the openings 372 may be sufficiently small to allow a sufficiently high potential difference between the upper plasma potential and the switchable plasma potential and to reduce any reverse ion current between the switchable plasma 353 and the upper plasma 313. Further, the one or more openings 372 may be sufficiently small to sustain a pressure difference between the first pressure in the upper plasma region 312 and the second pressure in the switchable plasma region 352.

Still referring to FIG. 3, the SQNB system 300 can include a pressure control system 354 that can be coupled to the SQNB process chamber 315. One or more of the controllers 395 can be coupled to the pressure control system 354, and at least one of the controllers 395 can be configured to control and/or monitor the pressure control system 354. In some examples, the pressure control system 354 can include a vacuum pump 358 and a vacuum valve 359 that can be coupled to the SQNB process chamber 315, and the pressure control system 354 can be configured to evacuate the SQNB process chamber 315 and control a pressure in the SQNB process chamber 315. Alternatively, the pressure control system 354 can be configured using a different number of pumps and/or a different number of flow control devices. The vacuum pump 358 can include a turbo-molecular vacuum pump (TMP) capable of a pumping speed up to 5000 liters per second (and greater), and the vacuum valve 359 can include a gate valve. The vacuum valve 359 can be coupled to an exhaust space formed at the bottom of the SQNB process chamber 315. Furthermore, one or more first sensors 338 for monitoring chamber conditions can be coupled to the SQNB process chamber 315, and one or more of the first sensors 338 can be used to measure pressure in the SQNB process chamber 315.

In addition, the switchable substrate holder 320 may be surrounded by a baffle member 321 that extends beyond a peripheral edge of the switchable substrate holder 320. The baffle member 321 may serve to uniformly distribute the pumping speed delivered by the pressure control system 354 to the switchable plasma region 352. The baffle member 321 may be fabricated from a dielectric material, such as quartz, or alumina. The baffle member 321 may provide a high RF impedance to ground for the switchable plasma 353.

In some embodiments, a transfer port 301 for a semiconductor substrate can be formed in the sidewall of the SQNB process chamber 315, and can be opened/closed by a gate valve 302 attached thereon. One or more of the controllers 395 can be coupled to gate valve 302, and at least one of the controllers 395 can be configured to control and/or monitor the gate valve 302. The patterned substrate 325 can be, for example, transferred into and out of SQNB process chamber 315 through transfer port 301 and gate valve 302 from a transfer subsystem (170, FIG. 1), and it can be received by substrate lift pins (not shown) housed within switchable substrate holder 320 and mechanically translated by devices (not show) housed therein. After the patterned substrate 325 is received from transfer system, it can be lowered to an upper surface of switchable substrate holder 320. The design and implementation of substrate lift pins are well known to those skilled in the art. Alternatively, an un-patterned substrate may be used.

The SQNB system 300 can include a switchable gas supply system 355 that can be coupled to switchable gas distribution element 357 in the SQNB process chamber 315 using at least one second supply line 356. One or more of the controllers 395 can be coupled to the switchable gas supply system 355, and at least one of the controllers 395 can be configured to control and/or monitor the switchable gas supply system 355. The switchable gas supply system 355 and the switchable gas distribution element 357 can be used to introduce at least one first SQNB process gas to the switchable plasma region 352 during a first SQNB procedure, can be used to introduce at least one second SQNB process gas to the switchable plasma region 352 during a second SQNB procedure, and can be used to introduce at least one second SQNB process gas to the switchable plasma region 352 during a second SQNB procedure. For example, the first and/or second SQNB process gas can include curing gas, drying gas, shrinking gas, correcting gas, hardening gas, etching gas, ashing gas, cleaning gas, or deposition gas, or any combination thereof. Alternatively, a different introduction method may be used.

The switchable gas distribution element 357 can be used to introduce the process gas to one or more zones in the switchable plasma region 352. In addition, the switchable gas distribution element 357 can be configured to provide different gasses at different flow rates to one or more of the zones in the switchable plasma region 352. Alternatively, a different introduction method may be used. The process gas can comprise an electropositive gas, or an electronegative gas, or a mixture thereof. For example, the process gas may comprise a noble gas, an oxygen-containing gas, a nitrogen-containing gas, a fluorine-containing gas, or a carbon-containing gas, or any combination thereof. In additional examples, the process gas can comprise any gas suitable for performing a SQNB procedure using the patterned substrate 325, and the first plasma generation gas can comprise any gas having chemical constituents, atomic or molecular, suitable for performing a SQNB procedure using the patterned substrate 325. These chemical constituents may comprise etchants, film-forming gases, dilutants, cleaning gases, etc. The switchable gas supply system 355 may include one or more gas supplies or gas sources, one or more control valves, one or more filters, one or more mass flow controllers, one or more measurement devices, etc. The second supply line 356 and/or the switchable gas distribution element 357 can include one or more control valves, one or more filters, one or more mass flow controllers, one or more switches, etc.

As shown in FIG. 3, the SQNB process chamber 315 can include one or more chamber liner members 316 that may be coupled to ground. For example, one or more chamber liner members 316 can be disposed between one or more of the walls of the SQNB process chamber and the switchable plasma 353 in the switchable plasma region 352. In addition, each chamber liner member 316 can be fabricated from a dielectric material, such as quartz or alumina, and the chamber liner member 316 can provide a high RF impedance to ground for the switchable plasma 353.

In addition, the SQNB process chamber 315 can include one or more lower bias electrodes 317 can be electrically insulated from the SQNB process chamber 315 using at least one insulator 318. The lower bias electrodes 317 can have at least one conductive surface in contact with the switchable plasma 353. The lower bias electrode 317 can comprise a conductive material, such as metal or doped silicon. Although a single lower bias electrode 317 is shown in FIG. 3, the SQNB system 300 can include one or more lower bias electrodes.

In some embodiments, the SQNB system 300 can include a bias power supply 380, a lower multi-position switch 382 that can be coupled to the lower power supply 380, and a lower feed-thru element 384. One or more of the controllers 395 can be coupled to the bias power supply 380 and/or to the lower multi-position switch 382, and at least one of the controllers 395 can be configured to control and/or monitor the bias power supply 380 and/or the lower multi-position switch 382. For example, the lower feed-thru element 384 can include a filter and/or a sensor and can be configured to allow electrical connection to the lower bias electrode 317. The lower feed-thru element 384 can be used to couple a first common port (d) of the lower multi-position switch 382 to the lower bias electrode 317 in the SQNB process chamber 315. In addition, the lower multi-position switch 382 can include a first switchable port (e) that can be coupled to the lower power supply 380 and can include a second switchable port (f) that can be coupled to a ground potential. When first position (path (d-e)) is used, the lower bias electrode 317 can be coupled to the lower power supply 380, and when second position (path (d-f)) is used, the lower bias electrode 317 can be coupled to the ground potential. For example, the lower power supply 380 can provide DC power, and/or AC power, and the output from the lower power supply 380 can be constant, varied, pulsed, stepped, and/or ramped.

In other embodiments, the lower bias electrode 317 may be coupled to ground, and the lower feed-thru element 384, the lower power supply 340, and/or the lower multi-position switch 382 may not be required. In still other embodiments, the lower bias electrode 317 may be coupled to the lower power supply 380.

The bias power supply 380 and the lower bias electrode 317 can be configured to elevate the switchable plasma potential to a value above the upper plasma potential in order to drive the electron flux in the correct direction. Although not necessary, it is desirable that the lower bias electrode 317 comprises a relatively large area in contact with the switchable plasma 353. The larger the area at the +V_{DC} potential, the closer the switchable plasma potential will be to +V_{DC}. As an example, the total area of the lower bias electrode 317 may be greater than the total sum of all other conductive surfaces that are in contact with the switchable plasma 353. Alternatively, as an example, the total area of the lower bias electrode 317 may be the only conductive surface that is in contact with the switchable plasma 353.

The bias power supply 380 can include a variable DC power supply. Additionally, the bias power supply 380 can include a bipolar DC power supply. The bias power supply 380 can further include a system configured to perform at least one of monitoring adjusting, or controlling the polarity, current, voltage, or on/off state of the bias power supply 380. An electrical filter may be utilized to de-couple RF power from the bias power supply 380.

For example, the DC voltage applied to the lower bias electrode 317 by bias power supply 380 may range from approximately 0 volts (V) to approximately 10000 V. Desirably, the DC voltage applied to the lower bias electrode 317 by bias power supply 380 may range from approximately 50 volts (V) to approximately 5000 V. Additionally, it is desirable that the DC voltage has a positive polarity. Furthermore, it is desirable that the DC voltage is a positive voltage having an absolute value greater than approximately 50 V.

Still referring to FIG. 3, the SQNB process chamber 315 can include a switchable substrate holder 320 configured to support the patterned substrate 325. The switchable substrate holder 320 can include electrostatic clamping (ESC) electrode 323 that can be coupled to a clamping supply 322 using at least one feed-thru (ft), and that can be used to affix the patterned substrate 325 to an upper surface of switchable substrate holder 320. One or more of the controllers 395 can be coupled to the clamping supply 322, and at least one of the controllers 395 can be configured to control and/or monitor the clamping supply 322. In some embodiments, the electrostatic clamping (ESC) electrode 323 and the clamping supply 322 can be used to improve the thermal transfer between the patterned substrate 325 and switchable substrate holder 320. In other embodiments, the electrostatic clamping (ESC) electrode 323 can be used to isolate the patterned substrate 325 from the switchable substrate holder 320.

In addition, the switchable substrate holder 320 can include backside gas elements 327 that can be coupled to a backside gas delivery system 326 using at least one feed-thru (ft), and that can be configured to introduce gas to the backside of the patterned substrate 325 in order to improve the gas-gap thermal conductance between the patterned substrate 325 and switchable substrate holder 320. One or more of the controllers 395 can be coupled to the backside gas delivery system 326, and at least one of the controllers 395 can be configured to control and/or monitor the backside gas delivery system 326. Such a system can be utilized when temperature control of the patterned substrate 325 is required at elevated or reduced temperatures. For example, the backside gas delivery system 326 can be coupled to two-zone (center/edge) backside gas elements 327, and the helium gas gap pressure can be independently varied between the center and the edge of the patterned substrate 325. In other embodiments, the backside gas elements 327 can be used to isolate the patterned substrate 325 from the switchable substrate holder 320.

In addition, the SQNB system 300 can include a temperature control system 328 coupled to the switchable substrate holder 320 using at least one feed-thru (ft), and can be configured to adjust and control the temperature of patterned substrate 325. The temperature control system 328 can be coupled to one or more temperature control elements 329. One or more of the controllers 395 can be coupled to the temperature control system 328, and at least one of the controllers 395 can be configured to control and/or monitor the temperature control system 328. For example, the temperature control elements 329 may be used to re-circulate heat-exchanging fluid. Additionally, the temperature control elements 329 can include heating/cooling elements, such as resistive heating elements, or thermo-electric heaters/coolers, which can be included in the switchable substrate holder 320, as well as the chamber wall of the SQNB process chamber 315 and any other component within the SQNB process chamber 315. In some embodiments, the two-zone backside gas elements 327 that are coupled to the backside gas delivery system 326 and the temperature control elements 329 that are coupled to the temperature control system 328 can be configured to establish a first edge temperature and a first center temperature for the substrate, and the first edge temperature and the first center temperature can be between about 0 degrees Celsius and about 100 degrees Celsius.

In still other embodiments, the SQNB system 300 can include additional substrate bias components, and the switchable substrate holder 320 can be electrically isolated from the bottom chamber wall in the SQNB process chamber 315 using at least one isolation element 335. The switchable substrate holder 320 can include a substrate bias electrode 333, which can be coupled to a bias generator 330, a filter network 331, a first multi-position switch 332, and/or a first feed-thru element 334. One or more of the controllers 395 can be coupled to the bias generator 330, the filter network 331, and/or the first multi-position switch 332, and at least one of the controllers 395 can be configured to control and/or monitor the bias generator 330, the filter network 331, and/or the first multi-position switch 332. For example, the first feed-thru element 334 can include a filter and/or a sensor and can be configured to allow electrical connection to the substrate bias electrode 333. The first feed-thru element 334 can be used to couple a common port (g) of the first multi-position switch 332 to the substrate bias electrode 333 in the switchable substrate holder 320. In addition, the first multi-position switch 332 can include a first switchable port (h) that can be coupled to a ground potential, can include a second switchable port (i) that can be isolated, and can include a first switchable port (j) that can be coupled to the filter network 331. When the first position (path (g-h)) is used, the substrate bias electrode 333 and/or the switchable substrate holder 320 can be coupled to the ground potential, when the second path (g-i) is used, the substrate bias electrode 333 and/or the switchable substrate holder 320 can be isolated, and when the third path (g-j) is used, the substrate bias electrode 333 and/or the switchable substrate holder 320 can be coupled to the bias generator 330 using the filter network 331. In some examples, the bias generator 330 can provide DC power, and/or AC power, and the output from the bias generator 330 can be constant, varied, pulsed, stepped, and/or ramped. In other examples, the bias generator 330 can provide one or more RF signals, the RF signal frequency can range from about 0.1 MHz to about 100 MHz, and the RF signal power can vary from approximately 10 watts to approximately 1000 watts during some SQNB procedures.

In other embodiments, the switchable substrate holder 320 may be coupled to ground or isolated, and the bias generator 330, the filter network 331, the first feed-thru element 334, the first multi-position switch 332 may not be required. In still other embodiments, the switchable substrate holder 320 may be coupled to ground or isolated using the bias generator 330 and/or the filter network 331.

When the switchable substrate holder 320 is coupled to ground, the patterned substrate 325 can be at floating ground and, therefore, the only ground the switchable plasma 353 contacts is the floating ground provided by patterned substrate 325. For example, when the patterned substrate 325 is clamped to switchable substrate holder 320, a ceramic electrostatic clamp (ESC) layer may insulate the patterned substrate 325 from the switchable substrate holder 320. For example, the ESC voltage can vary from approximately 2000 V to approximately 3000 V.

When a focus ring 306 is used, the focus ring 306 can include a silicon-containing material and can be disposed on the top of the switchable substrate holder 320. In some examples, focus ring 306 can be configured to surround the electrostatic electrode 323, the backside gas elements 327, and the patterned substrate 325 to improve uniformity at the edge of the substrate. In other examples, the focus ring 306 can include a correction ring portion (not shown) that can be used to modify the edge temperature of the patterned substrates 325. In various embodiments, conductive or non-conductive focus rings may be used.

When an inner deposition shield 308 is used, the inner deposition shield 308 can be detachably coupled to the substrate holder shield 307 to prevent by-products created during first and/or second SQNB procedures from being deposited on the switchable substrate holder 320. Alternatively, the inner deposition shield 308 and/or the substrate holder shield 307 may not be required. The baffle member 321 and the substrate holder shield 307 can include an aluminum body covered with a ceramic, such as Y₂O₃.

As depicted in FIG. 3, the SQNB system 300 can include one or more sensors (338, 339) that can include one or more optical devices for monitoring the light emitted from the switchable plasma 353 in the switchable plasma region 352, and/or one or more gas sensing devices for monitoring exhaust gasses. The sensors (338, 339) can include an optical sensor that can be used as an End Point Detector (EPD) and can provide EPD data. For example, an Optical Emission Spectroscopy (OES) sensor may be used. In addition, the sensors (338, 339) can include current and/or voltage probes, power meters, spectrum analyzers, or an RF Impedance analyzer, or any combination thereof. Furthermore, the measurement of an electrical signal, such as a time trace of voltage or current, permits the transformation of the signal into frequency domain using discrete Fourier series representation (assuming a periodic signal). Thereafter, the Fourier spectrum (or for a time varying signal, the frequency spectrum) can be monitored and analyzed to characterize the state of a plasma.

In addition, the SQNB system 300 can include one or more controllers 395 that can include one or more microprocessors, one or more memory elements, and one or more analog and/or digital I/O devices (potentially including D/A and/or A/D converters) capable of generating control voltages sufficient to communicate and activate inputs to the SQNB system 300 as well as monitor outputs from the SQNB system 300. As shown in FIG. 3, controller 395 can be coupled to and exchange information with gate valve 302, a clamping supply 322, backside gas delivery system 326, temperature control system 328, bias generator 330, filter network 331, first multi-position switch 332, sensors (338, 339), the upper power supply 340, the upper multi-position switch 342, the upper gas supply system 345, the switchable gas supply system 355, the pressure control system 354, plasma generation source 360, the bias power supply 380, and the lower multi-position switch 382. One or more programs stored in the memory can be utilized to interact with the aforementioned components of the SQNB system 300 according to stored process recipes.

One or more of the controllers 395 may be implemented as a general-purpose computer system that performs a portion or all of the microprocessor based processing steps of the invention in response to a controller/processor executing one or more sequences of one or more instructions contained in a memory. Such instructions may be read into the controller memory from another computer readable medium, such as a hard disk or a removable media drive. One or more processors in a multi-processing arrangement may also be employed as the control microprocessor to execute the sequences of instructions contained in main memory. In alternative embodiments, hard-wired circuitry may be used in place of or in combination with software instructions. Thus, embodiments are not limited to any specific combination of hardware circuitry and software.

In various embodiments, the plasma species associated with the upper gas supply system 345 can include Ar, CF₄, F₂, C₄F₈, CO, C₅F₈, C₄F₆, CHF₃, N₂/H₂, or HBr, or any combination of two or more thereof. The plurality of first gas distribution elements 347 can provide different flow rates to different regions of the upper plasma region 312. In addition, the plasma species associated with the switchable gas supply system 355 can include Ar, CF₄, F₂, C₄F₈, CO, C₅F₈, C₄F₆, CHF₃, N₂/H₂, or HBr, or any combination of two or more thereof. The plurality of first SQNB process gas distribution elements 357 can provide different flow rates to different regions of the switchable plasma region 352.

When the first plasma generation gas and or the first SQNB process gas includes at least one fluorocarbon gas and at least one inert gas, a first fluorocarbon gas flow rate varying between approximately 10 sccm and approximately 50 sccm and a first inert gas flow rate varying between approximately 3 sccm and approximately 20 sccm, and the fluorocarbon gas comprises C₄F₆, C₄F₈, C₅F₈, CHF₃, or CF₄, or any combination thereof, and the inert gas can comprises Ar, Helium (He), Krypton (Kr), Neon (Ne), Radon (Rn), or Xenon (Xe), or any combination thereof.

When the first plasma generation gas and or the first SQNB process gas include CO, the CO flow rate can vary between approximately 2 sccm and approximately 20 sccm.

As an example, in an electropositive discharge, the electron density may range from approximately 10¹⁰ cm⁻³ to 10¹³ cm⁻³, and the electron temperature may range from about 1 eV to about 10 eV (depending on the type of plasma source utilized).

As illustrated in FIG. 3, the plurality of beams 350 can include an electron flux that occurs between the upper plasma region 312 and the switchable plasma region 352 through separation member 370. The electron transport is driven by electric field-enhanced diffusion, wherein the electric field is established by the potential difference between the upper plasma potential and the switchable plasma potential. The plurality of beams 350 can include an electron flux that can be sufficiently energetic to sustain ionization in the switchable plasma 353.

When a first and/or second SQNB process are performed by the SQNB system 300, the gate valve 302 can be opened, and a patterned substrate 325 can be transferred into the SQNB process chamber 315 and placed on the switchable substrate holder 320. The plasma generation chamber 310 can provide a upper plasma species and the SQNB process chamber 315 can be configured to use a upper plasma species to facilitate the generation of switchable plasma 353 in switchable plasma region 352 adjacent a surface of the patterned substrate 325. The switchable plasma species can include a fluorocarbon element (CₓF_{y}), such as C₄F₈, and may contain another component, such as Ar, or CO. The flow rate for the upper plasma species (ions) and/or the electrons can be established using the first and/or second SQNB process recipe. During the first SQNB procedures, an ionizable gas or mixture of gases can introduced from the switchable gas supply system 355, and process pressure can be adjusted using pressure control system 354. In addition, an ionizable process gas or mixture of process gases can be introduced from the switchable gas supply system 355, and process pressure can be adjusted using pressure control system 354 during the SQNB processing procedures. For example, the pressure inside plasma generation chamber 310 can range from about 1 millitorr (mtorr) to about 1200 mtorr, and the pressure inside the SQNB process chamber 315 can range between about 0.1 mtorr and about 150 mtorr during various first and/or second SQNB procedures. In other examples, the pressure inside plasma generation chamber 310 can range from about 10 mtorr to about 150 mtorr, and the pressure inside the SQNB process chamber 315 can range between about 1 mtorr and about 15 mtorr during other SQNB first and/or second SQNB procedures.

During some SQNB processing procedures, a RF signal can be applied from the bias generator 330 to the substrate bias electrode 333 at a predetermined power level to maintain and control the switchable plasma 353 that is created in the switchable plasma region 352. For example, the RF signal may provide ion attraction to the lower electrode at one or more signal power levels when the upper plasma species, electrons, and/or the process gas are supplied into the SQNB process chamber 315. In addition, a predetermined DC voltage can be applied from the bias power supply 380 to one or more of the DC conductive bias electrodes. Furthermore, another DC voltage can be applied from the clamping supply 322 to the electrostatic electrode 323 to fix the semiconductor substrate on the switchable substrate holder 320. Radicals and ions generated in the switchable plasma 353 can be used to process the photoresist layer on the patterned substrate 325.

One or more of the sensors (338, 339) can be configured to detect the plasma state, so that the controller 395 can control the SQNB subsystem 305, the first SQNB procedure (recipe) parameters, and/or the second SQNB procedure (recipe) parameters using the detected plasma state. In addition, one or more of the sensors (338, 339) can be used to measure the plasma sheath length and/or the electron density during the first and/or second SQNB procedures.

When the photo-resist film on the patterned substrate 325 includes 193 nm photoresist material, the 193 nm photoresist material changes its polymer structure when it is radiated with electrons during a SQNB curing procedure. When the composition of the 193 nm photoresist material is reformed due to the resist cross-linkage reaction, the etching resistance property of the 193 nm photoresist material can increase, and the surface roughness of the 193 nm photoresist material can decrease. Therefore, the plasma state can be controlled by the controller 395 to enhance the etching resistance property of the 193 nm photoresist material (particularly, ArF resist material) by irradiation with electrons.

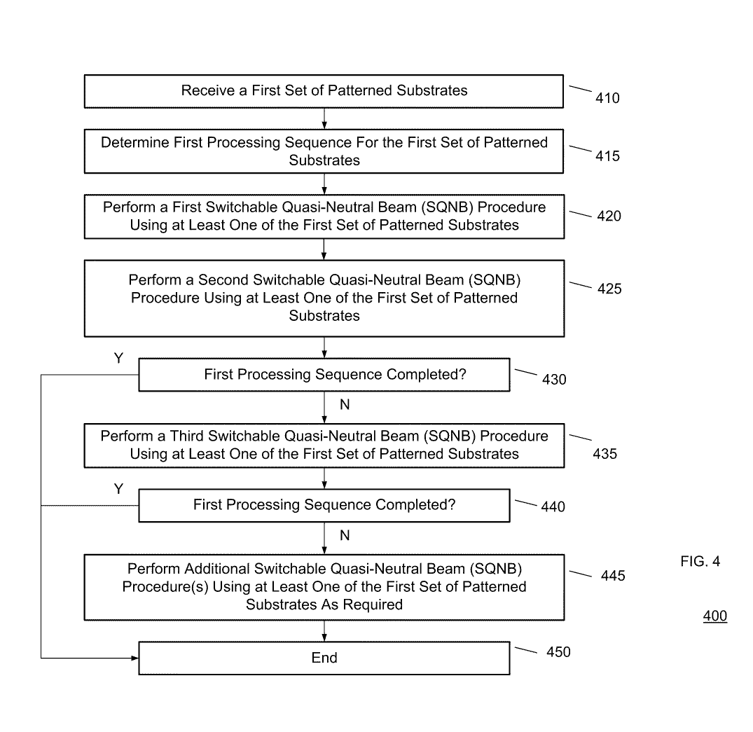

FIG. 4 shows an exemplary flow diagram of a switched quasi-neutral beam (SQNB) procedure in accordance with embodiments of the invention. In the illustrated embodiment, a procedure 400 is provided for performing one or more SQNB processes on one or more patterned substrates using a SQNB subsystem such as shown in FIGS. 2A, 2B, and 3. For example, the SQNB processes can include masking layer curing, drying, shrinking, correcting, and/or hardening procedures, etch procedures, ashing procedures, cleaning procedures, or deposition procedures, or any combination thereof.

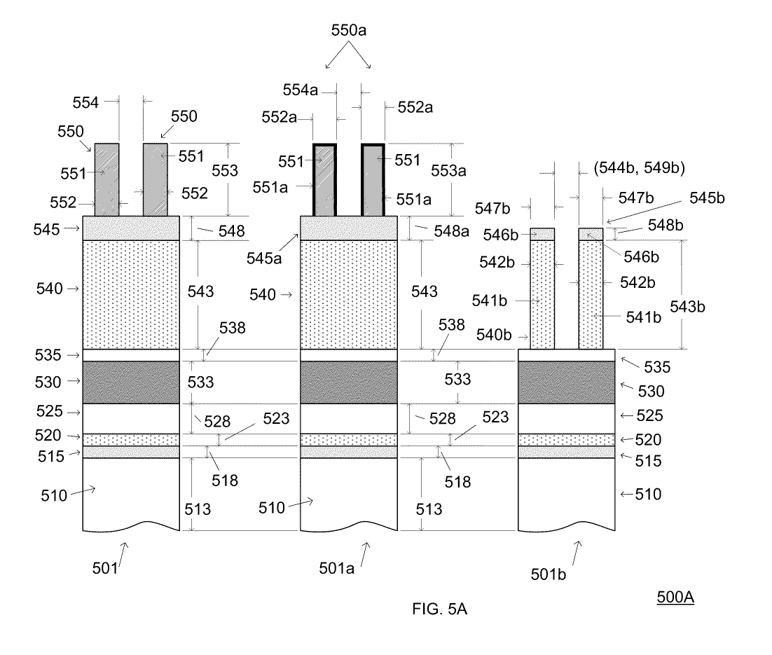

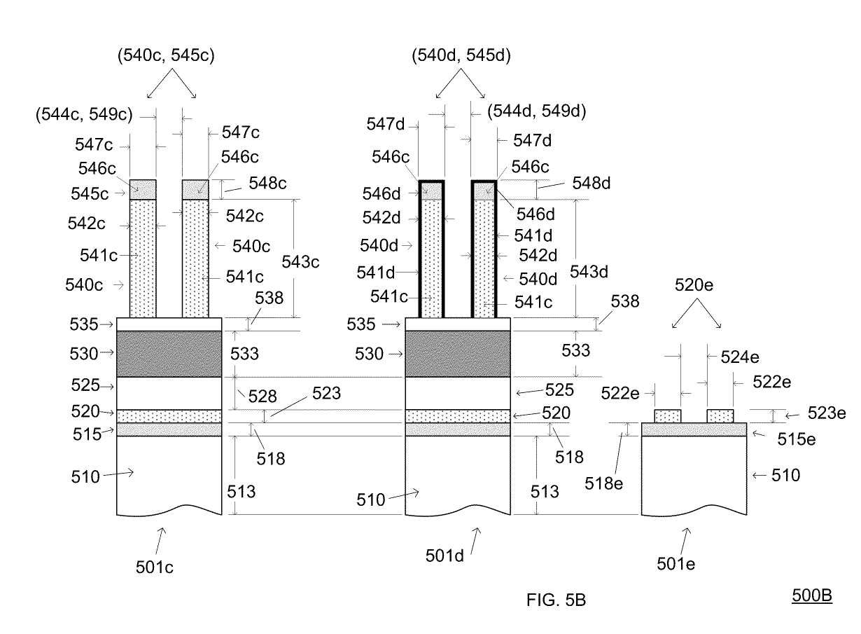

In 410, a first set of patterned substrates can be received by a transfer subsystem (170, FIG. 1) that can be coupled to one or more of the subsystems (110, 120, 130, 140, 150, 160, and 170). Alternatively, un-patterned substrates may be received by the transfer subsystem (170, FIG. 1). Each patterned substrate can have a plurality of first gate stacks (501, FIG. 5A) thereon, and the first gate stacks (501, FIG. 5A) can include a plurality of gate-related masking features (550, FIG. 5A) and a plurality of additional layers (510, 515, 520, 525, 530, 535, 540, and 545, FIG. 5A-5B). Alternatively, the first gate stack (501, FIG. 5A) may be configured differently. One or more of the controllers (114, 124, 134, 144, 154, 164, and 190) can be used to receive, determine, and/or send real-time and/or historical data associated with one or more of the first set of patterned substrates.

In 415, a first SQNB-related processing sequence can be determined for the first set of patterned substrates using one or more of the controllers (114, 124, 134, 144, 154, 164, and 190). The first SQNB-related processing sequence can include one or more curing procedures, one or more drying procedures, one or more shrinking procedures, one or more correcting procedures, one or more hardening procedures, one or more etch procedures, one or more ashing procedures, one or more cleaning procedures, one or more evaluation procedures, one or more verification procedures one or more measurement procedures, or one or more deposition procedures, or any combination thereof.

In some embodiments, the procedures in the first SQNB-related processing sequence can be performed using the SQNB subsystem (150, FIG. 1) that can be configured as shown in FIGS. 2A, 2B and 3. In other embodiments, the procedures in the first SQNB-related processing sequence can be performed using one or more of the other subsystems (110, 120, 130, 140, 160, and 170). In addition, the verification procedures can be performed using one or more of the subsystems (110, 120, 130, 140, 150, 160, and 170). For example, metrology data and/or CDSEM data can be obtained for the first set of patterned substrates using the evaluation subsystem (160, FIG. 1), and Optical Digital Profilometry (ODP) models can be used to provide metrology data for the gate stacks (501a-501c, FIG. 5A) and (501c-501e, FIG. 5B). In addition, the metrology data can include profile data, period data, wavelength data, diffraction signal data, reflection data, CD data, and SWA data.

In 420, a first SQNB procedure can be performed. A first patterned substrate, which can be selected from the first set of patterned substrates, can be processed using the first SQNB procedure. For example, the first SQNB procedure can be used to modify and/or evaluate a masking layer. The first patterned substrate can be positioned on a switchable substrate holder (320, FIG. 3) in a SQNB process chamber (315, FIG. 3), and the switchable substrate holder (320, FIG. 3) can be electrically isolated from the bottom chamber wall in the SQNB process chamber (315, FIG. 3) using at least one isolation element (335, FIG. 3).

The first patterned substrate can have a plurality of first gate stacks (501, FIG. 5A) thereon, and the first gate stacks (501, FIG. 5A) can include a plurality of masking features (550, FIG. 5A), which can be metal gate-related, and a plurality of additional layers (510, 515, 520, 525, 530, 535, 540, and 545, FIG. 5A-5B), which can include one or more metal gate-related layers. Alternatively, the first gate stack (501, FIG. 5A) may be configured differently and may be used in poly-gate procedures. In some examples, the first SQNB resist-modification procedure can be used to shrink, correct, protect, cure, and/or harden the masking features (550, FIG. 5A) in the first gate stack (501, FIG. 5A) to create a plurality of modified, cured, shrunk, protected, and/or hardened masking features (550a, FIG. 5A) as shown in the second gate stack (501a, FIG. 5A). Alternatively, first gate stack (501, FIG. 5A) and/or second gate stack (501a, FIG. 5A) may be configured differently.

During the first SQNB resist-modification procedure, first upper plasma can be created using a first plasma generation gas in an upper plasma region at a first upper plasma potential. In various examples, the first plasma generation gas can include Ar, CF₄, F₂, O₂, N₂, CO, C₄F₈, C₅F₈, C₄F₆, CHF₃, N₂/H₂, or HBr, or any combination of two or more thereof. The plurality of first gas distribution elements (347, FIG. 3) can provide different flow rates to different regions of the upper plasma region (312, FIG. 3).

In some embodiments, the upper multi-position switch (342, FIG. 3) can be used to couple the upper DC conductive electrode (311, FIG. 3) to a ground potential during some parts of the first SQNB resist-modification procedure, and the upper multi-position switch (342, FIG. 3) can be used to couple the upper DC conductive electrode (311, FIG. 3) to the upper power supply (340, FIG. 3) during other parts of the first SQNB resist-modification procedure to control the first upper plasma potential. In other embodiments, the upper multi-position switch (342, FIG. 3) can be used to couple the upper DC conductive electrode (311, FIG. 3) to a ground potential during substantially all of the first SQNB resist-modification procedure to control the first upper plasma potential. In some other embodiments, the upper multi-position switch (342, FIG. 3) can be used to couple the upper DC conductive electrode (311, FIG. 3) to the upper power supply (340, FIG. 3) during substantially all of the first SQNB resist-modification procedure to control the first upper plasma potential. For example, the upper power supply (340, FIG. 3) can provide DC power and/or AC power, and the output from the upper power supply (340, FIG. 3) can be constant, varied, pulsed, stepped, and/or ramped to control the first upper plasma potential during the first SQNB resist-modification procedures.

First SQNB resist-modification plasma can also be formed in a switchable plasma region at a first SQNB plasma potential using electron flux from the first upper plasma. Electron flux from the first upper plasma in the upper plasma region passes from the plasma generation chamber through a separation member to a SQNB process chamber where the first SQNB resist-modification plasma can be created. As illustrated in FIGS. 2A, 2B, and 3, the switchable plasma region may be located in a SQNB process chamber, and one or more openings or passages in the separation member disposed between the plasma generation chamber and the SQNB process chamber can be used to facilitate the transport or supply of electrons and one or more plasma species from the upper plasma region to the switchable plasma region.

In addition, the first SQNB resist-modification plasma potential can be elevated above the first upper plasma potential to control the electron flux. The first upper plasma in the upper plasma region may be a boundary-driven plasma (i.e., the plasma boundary has a substantive influence on the respective plasma potential), and part of or the entire boundary in contact with the first plasma can be coupled to DC ground. Additionally, the first SQNB resist-modification plasma in the switchable plasma region may be boundary-driven plasma, wherein part or the entire boundary in contact with the switchable plasma is coupled to a DC voltage source at +V_{DC}. The elevation of the first SQNB plasma potential above the first upper plasma potential may be performed using any one or combination of the embodiments provided in FIGS. 2A, 2B, and 3.

In some alternate embodiments, the lower multi-position switch (382, FIG. 3) can be used to couple the lower bias electrode (317, FIG. 3) to a ground potential during some parts of the first SQNB resist-modification procedure, and the lower multi-position switch (382, FIG. 3) can be used to couple the lower bias electrode (317, FIG. 3) to the bias power supply (380, FIG. 3) during other parts of the first SQNB resist-modification procedure to control the first SQNB plasma potential. In other alternate embodiments, the lower multi-position switch (382, FIG. 3) can be used to couple the lower bias electrode (317, FIG. 3) to a ground potential during substantially all of the first SQNB resist-modification procedure to control the first SQNB plasma potential. In some other alternate embodiments, the lower multi-position switch (382, FIG. 3) can be used to couple the lower bias electrode (317, FIG. 3) to the bias power supply (380, FIG. 3) during substantially all of the first SQNB resist-modification procedure to control the first SQNB plasma potential. For example, the bias power supply (380, FIG. 3) can provide DC power, and/or AC power, and the output from the bias power supply (380, FIG. 3) can be constant, varied, pulsed, stepped, and/or ramped to control the first SQNB processing plasma potential during the first SQNB resist-modification procedures.

Furthermore, the pressure in the SQNB process chamber can be controlled by pumping the SQNB process chamber and by controlling the flow rate for the first resist-modification gases entering the SQNB process chamber during the first SQNB resist-modification procedure. In various examples, the first resist-modification gases can include Ar, CF₄, F₂, O₂, N₂, CO, C₄F₈, C₅F₈, C₄F₆, CHF₃, N₂/H₂, or HBr, or any combination of two or more thereof. The plurality of second gas distribution elements (357, FIG. 3) can provide different flow rates to different regions of the switchable plasma region (352, FIG. 3). The patterned substrate can be exposed to the first SQNB plasma in the switchable plasma region during the first SQNB resist-modification procedure. The exposure of the substrate to the first SQNB processing plasma may comprise exposing the substrate to a mono-energetic space-charge neutralized neutral beam activated chemical process.

In some additional embodiments, the first multi-position switch (332, FIG. 3) can be used to couple the switchable substrate holder (320, FIG. 3) to a ground potential during some parts of the first SQNB resist-modification procedure, the first multi-position switch (332, FIG. 3) can be used to isolate the switchable substrate holder (320, FIG. 3) to during other parts of the first SQNB resist-modification procedure, and/or the first multi-position switch (332, FIG. 3) can be used to couple the switchable substrate holder (320, FIG. 3) to the bias power supply (380, FIG. 3) during still other parts of the first SQNB resist-modification procedure to control the first SQNB plasma. In other additional embodiments, the first multi-position switch (332, FIG. 3) can be used to couple the switchable substrate holder (320, FIG. 3) to a ground potential during substantially all of the first SQNB resist-modification procedure to control the first SQNB processing plasma. In still other additional embodiments, the first multi-position switch (332, FIG. 3) can be used to isolate the switchable substrate holder (320, FIG. 3) during substantially all of the first SQNB resist-modification procedure to control the first SQNB processing plasma. In some other additional embodiments, the first multi-position switch (332, FIG. 3) can be used to couple the switchable substrate holder (320, FIG. 3) to the bias power supply (380, FIG. 3) during substantially all of the first SQNB resist-modification procedure to control the first SQNB processing plasma.

In 425, one or more second SQNB procedures can be performed, and the second SQNB procedure can include feature-forming and/or feature-modifying sequences that can include measuring processes, evaluation processes, verification processes, etch processes, ash processes, developing processes, or other resist-removal processes. In some embodiments, the second SQNB procedure can be used to process a second gate stack (501a, FIG. 5A) to create a third (new) gate stack (501b, FIG. 5A). A first substrate having a pattern of modified masking features (550a, FIG. 5A) thereon can be processed using the second SQNB procedure. For example, each substrate that requires feature-forming and/or feature-modifying sequences can be positioned on a switchable substrate holder (320, FIG. 3) in a SQNB process chamber (315, FIG. 3), and the switchable substrate holder (320, FIG. 3) can be electrically isolated from the bottom chamber wall in the SQNB process chamber (315, FIG. 3) using at least one isolation element (335, FIG. 3).

The first patterned substrate can have a plurality of second gate stacks (501a, FIG. 5A) thereon, and the second gate stacks (501a, FIG. 5A) can include a plurality of modified masking features (550a, FIG. 5A), which can be metal gate-related, and a plurality of additional layers (510, 515, 520, 525, 530, 535, 540, and 545, FIG. 5A-5B), which can include one or more metal gate-related layers. Alternatively, second gate stacks (501a, FIG. 5A) may be configured differently and may be used in poly-gate procedures. In addition, the second SQNB procedure can use the modified masking features (550, FIG. 5A) in the second gate stack (501a, FIG. 5A) to create a plurality of processed (etched) gate-width control features (540b, FIG. 5) and a plurality of processed (etched) third hard mask features (545b, FIG. 5A) as shown in the third gate stack (501b, FIG. 5A). Alternatively, second gate stack (501a, FIG. 5A) and/or third gate stack (501b, FIG. 5A) may be configured differently.

During the second SQNB procedure, second upper plasma can be created using a second plasma generation gas in upper plasma region at a second upper plasma potential. In various examples, the second plasma generation gas can include Ar, CF₄, F₂, O₂, N₂, CO, C₄F₈, C₅F₈, C₄F₆, CHF₃, N₂/H₂, or HBr, or any combination of two or more thereof. The plurality of first gas distribution elements (347, FIG. 3) can provide different flow rates to different regions of the upper plasma region (312, FIG. 3).

In some embodiments, the upper multi-position switch (342, FIG. 3) can be used to couple the upper DC conductive electrode (311, FIG. 3) to a ground potential during some parts of the second SQNB procedure, and the upper multi-position switch (342, FIG. 3) can be used to couple the upper DC conductive electrode (311, FIG. 3) to the upper power supply (340, FIG. 3) during other parts of the second SQNB procedure to control the second upper plasma potential. In other embodiments, the upper multi-position switch (342, FIG. 3) can be used to couple the upper DC conductive electrode (311, FIG. 3) to a ground potential during substantially all of the second SQNB procedure to control the second upper plasma potential. In some other embodiments, the upper multi-position switch (342, FIG. 3) can be used to couple the upper DC conductive electrode (311, FIG. 3) to the upper power supply (340, FIG. 3) during substantially all of the second SQNB procedure to control the second upper plasma potential. For example, the upper power supply (340, FIG. 3) can provide DC power and/or AC power, and the output from the upper power supply (340, FIG. 3) can be constant, varied, pulsed, stepped, and/or ramped to control the second upper plasma potential during the second SQNB procedures.

Second SQNB processing plasma can also be formed in a switchable plasma region at a second SQNB processing plasma potential using electron flux from the second upper plasma. Electron flux from the second upper plasma in the upper plasma region passes from the plasma generation chamber through a separation member to a SQNB process chamber where the second SQNB processing plasma can be created. As illustrated in FIGS. 2A, 2B, and 3, the switchable plasma region may be located in a SQNB process chamber, wherein one or more openings or passages in the separation member disposed between the plasma generation chamber and the SQNB process chamber can facilitate the transport or supply of electrons and one or more plasma species from the upper plasma region to the switchable plasma region during the second SQNB procedure.

In addition, the second SQNB processing plasma potential can be elevated above the second upper plasma potential to control the electron flux. The second upper plasma in the upper plasma region may be a boundary-driven plasma (i.e., the plasma boundary has a substantive influence on the respective plasma potential), wherein part or the entire boundary in contact with the second upper plasma is coupled to DC ground. Additionally, the second SQNB processing plasma in the switchable plasma region may be boundary-driven plasma, wherein part or the entire boundary in contact with the second SQNB processing plasma is coupled to a DC voltage source at +VDC. The elevation of the second SQNB processing plasma potential above the second upper plasma potential may be performed using any one or combination of the embodiments provided in FIGS. 2A, 2B, and FIG. 3.

In some alternate embodiments, the lower multi-position switch 382, FIG. 3) can be used to couple the lower bias electrode (317, FIG. 3) to a ground potential during some parts of the second SQNB procedure, and the lower multi-position switch (382, FIG. 3) can be used to couple the lower bias electrode (317, FIG. 3) to the bias power supply (380, FIG. 3) during other parts of the second SQNB procedure to control the second SQNB processing plasma potential. In other alternate embodiments, the lower multi-position switch (382, FIG. 3) can be used to couple the lower bias electrode (317, FIG. 3) to a ground potential during substantially all of the second SQNB procedure to control the second SQNB processing plasma potential. In some other alternate embodiments, the lower multi-position switch (382, FIG. 3) can be used to couple the lower bias electrode (317, FIG. 3) to the bias power supply (380, FIG. 3) during substantially all of the second SQNB procedure to control the second SQNB processing plasma potential. For example, the bias power supply (380, FIG. 3) can provide DC power and/or AC power, and the output from the bias power supply (380, FIG. 3) can be constant, varied, pulsed, stepped, and/or ramped to control the second SQNB processing plasma potential during the second SQNB procedure.

Furthermore, the pressure in the SQNB process chamber can be controlled by pumping the SQNB process chamber and by controlling the flow rate for the second SQNB process gases entering the SQNB process chamber during the second SQNB procedure, and the second SQNB procedure can include one or more etch processes, one or more ash processes, one or more developing procedures, or one or more other resist removal process. In various examples, the second SQNB process gases can include Ar, CF₄, F₂, O₂, N₂, CO, C₄F₈, C₅F₈, C₄F₆, CHF₃, N₂/H₂, or H Br, or any combination of two or more thereof. The plurality of second gas distribution elements (357, FIG. 3) can provide different flow rates to different regions of the switchable plasma region (352, FIG. 3). The patterned substrate can be exposed to the second SQNB processing plasma in the switchable plasma region. The exposure of the substrate to second SQNB processing plasma may comprise exposing the substrate to a mono-energetic space-charge neutralized neutral beam activated chemical process.

In some additional embodiments, the first multi-position switch (332, FIG. 3) can be used to couple the switchable substrate holder (320, FIG. 3) to a ground potential during some parts of the second SQNB procedure, the first multi-position switch (332, FIG. 3) can be used to isolate the switchable substrate holder (320, FIG. 3) during other parts of the second SQNB procedure, and/or the first multi-position switch (332, FIG. 3) can be used to couple the switchable substrate holder (320, FIG. 3) to the bias power supply (380, FIG. 3) during still other parts of the second SQNB procedure to control the second SQNB processing plasma. In other additional embodiments, the first multi-position switch (332, FIG. 3) can be used to couple the switchable substrate holder (320, FIG. 3) to a ground potential during substantially all of the second SQNB procedure to control the second SQNB processing plasma. In still other additional embodiments, the first multi-position switch (332, FIG. 3) can be used to isolate the switchable substrate holder (320, FIG. 3) during substantially all of the second SQNB procedure to control the second SQNB processing plasma. In some other additional embodiments, the first multi-position switch (332, FIG. 3) can be used to couple the switchable substrate holder (320, FIG. 3) to the bias power supply (380, FIG. 3) during substantially all of the second SQNB procedure to control the second SQNB processing plasma.

In 430, a query can be performed to determine if the first processing sequence has been completed. When the first processing sequence has been completed, procedure 400 can branch to step 450. When the first processing sequence has not been completed, procedure 400 can branch to step 435 and continue as shown in FIG. 4.

In 435, one or more third SQNB procedures can be performed. In some embodiments, the third SQNB procedure can be used to modify a fourth gate stack (501c, FIG. 5B) to create a fifth (new) gate stack (501d, FIG. 5B). During some processing sequences, a first previously-processed substrate, which can be selected from a first set of previously-processed substrates, can be further processed using the third SQNB procedure. The first previously-processed substrate can have a plurality of previously-processed gate-width control features (540c, FIG. 5B), which can be metal gate-related, and a plurality of previously-processed third hard mask features (545c, FIG. 5B) as shown in the fourth gate stack (501c, FIG. 5B) which can be metal gate-related. Alternatively, the fourth gate stack (501c, FIG. 5B) and/or the fifth (new) gate stack (501d, FIG. 5B) may be configured differently and may be used in poly-gate procedures.

During the third SQNB procedure, the first previously-processed substrate can be positioned on a switchable substrate holder (320, FIG. 3) in a SQNB process chamber (315, FIG. 3), and the switchable substrate holder (320, FIG. 3) can be electrically isolated from the bottom chamber wall in the SQNB process chamber (315, FIG. 3) using at least one isolation element (335, FIG. 3). In addition, the third SQNB procedure can be used to modified the plurality of previously-processed gate-width control features (540c, FIG. 5B) and the plurality of previously-processed third hard mask features (545c, FIG. 5B) in the fourth gate stack (501c, FIG. 5B) to create a plurality of modified gate-width control features (540d, FIG. 5B) and/or a plurality of modified third hard mask features (545d, FIG. 5B) as shown in the fifth gate stack (501d, FIG. 5B). Alternatively, the fourth gate stack (501c, FIG. 5B) and/or the fifth gate stack (501d, FIG. 5B) may be configured differently.

During the third SQNB procedure, third upper plasma can be created using one or more third plasma generation gases in an upper plasma region at a third upper potential. In various examples, the third plasma generation gases can include Ar, CF₄, F₂, O₂, N₂, CO, C₄F₈, C₅F₈, C₄F₆, CHF₃, N₂/H₂, or HBr, or any combination of two or more thereof. The plurality of first gas distribution elements (347, FIG. 3) can provide different flow rates to different regions of the upper plasma region (312, FIG. 3) for one or more of the third plasma generation gases.

In some embodiments, the upper multi-position switch (342, FIG. 3) can be used to couple the upper DC conductive electrode (311, FIG. 3) to a ground potential during some parts of the third SQNB procedure, and the upper multi-position switch (342, FIG. 3) can be used to couple the upper DC conductive electrode (311, FIG. 3) to the upper power supply (340, FIG. 3) during other parts of the third SQNB procedure to control the third upper plasma potential. In other embodiments, the upper multi-position switch (342, FIG. 3) can be used to couple the upper DC conductive electrode (311, FIG. 3) to a ground potential during substantially all of the third SQNB procedure to control the third upper plasma potential. In some other embodiments, the upper multi-position switch (342, FIG. 3) can be used to couple the upper DC conductive electrode (311, FIG. 3) to the upper power supply (340, FIG. 3) during substantially all of the third SQNB procedure to control the third upper plasma potential. For example, the upper power supply (340, FIG. 3) can provide DC power and/or AC power, and the output from the upper power supply (340, FIG. 3) can be constant, varied, pulsed, stepped, and/or ramped to control the third upper plasma potential during the third SQNB procedure.

A third SQNB processing plasma can also be formed in a switchable plasma region at a third SQNB processing plasma potential using electron flux from the third upper plasma. Electron flux from the third upper plasma in the upper plasma region passes from the plasma generation chamber through a separation member to a SQNB process chamber where the third SQNB processing plasma can be created. As illustrated in FIGS. 2A, 2B, and 3, the switchable plasma region may be located in a SQNB process chamber. For example, one or more openings or passages in the separation member can be disposed between the plasma generation chamber and the SQNB process chamber to facilitate the transport or supply of electrons from the upper plasma region to the switchable plasma region in the SQNB process chamber.

In addition, the third SQNB processing plasma potential can be elevated above the third upper plasma potential to control the electron flux. The third upper plasma in the upper plasma region may be a boundary-driven plasma (i.e., the plasma boundary has a substantive influence on the respective plasma potential), and part or the entire boundary can be in contact with the third upper plasma can be coupled to DC ground. Additionally, the third SQNB processing plasma in the switchable plasma region may be boundary-driven plasma, and part or the entire boundary that is in contact with the switchable plasma can be coupled to a DC voltage source at +VDC. The elevation of the third SQNB processing plasma potential above the third upper plasma potential may be performed using any one or combination of the embodiments provided in FIGS. 2A, 2B, and 3.

In some alternate embodiments, the lower multi-position switch 382, FIG. 3) can be used to couple the lower bias electrode (317, FIG. 3) to a ground potential during some parts of the third SQNB procedure, and the lower multi-position switch (382, FIG. 3) can be used to couple the lower bias electrode (317, FIG. 3) to the bias power supply (380, FIG. 3) during other parts of the third SQNB procedure to control the third SQNB processing plasma potential. In other alternate embodiments, the lower multi-position switch (382, FIG. 3) can be used to couple the lower bias electrode (317, FIG. 3) to a ground potential during substantially all of the third SQNB procedure to control the third SQNB processing plasma potential. In some other alternate embodiments, the lower multi-position switch (382, FIG. 3) can be used to couple the lower bias electrode (317, FIG. 3) to the bias power supply (380, FIG. 3) during substantially all of the third SQNB procedure to control the third SQNB processing plasma potential. For example, the bias power supply (380, FIG. 3) can provide DC power and/or AC power, and the output from the bias power supply (380, FIG. 3) can be constant, varied, pulsed, stepped, and/or ramped to control the third SQNB processing plasma potential during the third SQNB procedures.

Furthermore, the pressure in the SQNB process chamber can be controlled by pumping the SQNB process chamber and by controlling the flow rate for the third SQNB processing gases entering the SQNB process chamber during the third SQNB procedure. In various examples, the third SQNB processing gases can include Ar, CF₄, F₂, O₂, N₂, CO, C₄F₈, C₅F₈, C₄F₆, CHF₃, N₂/H₂, or HBr, or any combination of two or more thereof. The plurality of second gas distribution elements (357, FIG. 3) can provide different flow rates for the third SQNB processing gases to different regions of the switchable plasma region (352, FIG. 3) during the third SQNB procedure. The patterned substrate can be exposed to the third SQNB processing plasma in the switchable plasma region. The exposure of the substrate to the third SQNB processing plasma may comprise exposing the substrate to a third mono-energetic space-charge neutralized neutral beam activated chemical process.

In some additional embodiments, the first multi-position switch (332, FIG. 3) can be used to couple the switchable substrate holder (320, FIG. 3) to a ground potential during some parts of the third SQNB procedure, the first multi-position switch (332, FIG. 3) can be used to isolate the switchable substrate holder (320, FIG. 3) to during other parts of the third SQNB procedure, and/or the first multi-position switch (332, FIG. 3) can be used to couple the switchable substrate holder (320, FIG. 3) to the bias power supply (380, FIG. 3) during still other parts of the third SQNB procedure to control the third SQNB processing plasma. In other additional embodiments, the first multi-position switch (332, FIG. 3) can be used to couple the switchable substrate holder (320, FIG. 3) to a ground potential during substantially all of the third SQNB procedure to control the third SQNB processing plasma. In still other additional embodiments, the first multi-position switch (332, FIG. 3) can be used to isolate the switchable substrate holder (320, FIG. 3) during substantially all of the third SQNB procedure to control the third SQNB processing plasma. In some other additional embodiments, the first multi-position switch (332, FIG. 3) can be used to couple the switchable substrate holder (320, FIG. 3) to the bias power supply (380, FIG. 3) during substantially all of the third SQNB procedure to control the third SQNB processing plasma.

In 440, a query can be performed to determine if the first processing sequence has been completed. When the first processing sequence has been completed, procedure 400 can branch to step 450. When the first processing sequence has not been completed, procedure 400 can branch to step 445 and continue as shown in FIG. 4.

In 445, one or more fourth SQNB procedures can be performed. In some embodiments, the fourth SQNB procedure can use the fifth gate stack (501d, FIG. 5B) to create a sixth (new) gate stack (501e, FIG. 5B). Alternatively, the fifth gate stack (501d, FIG. 5B) and/or sixth gate stack (501e, FIG. 5B) may be configured differently. Each substrate that requires the fourth SQNB procedure can be positioned on a switchable substrate holder (320, FIG. 3) in a SQNB process chamber (315, FIG. 3), and the switchable substrate holder (320, FIG. 3) can be electrically isolated from the bottom chamber wall in the SQNB process chamber (315, FIG. 3) using at least one isolation element (335, FIG. 3).

Each substrate that requires the fourth SQNB procedure can have a plurality of fifth gate stacks (501d, FIG. 5B) thereon, and the fifth gate stacks (501d, FIG. 5B) can include a plurality of previously modified gate-width control features (540d, FIG. 5B) and a plurality of previously modified third hard mask features (545d, FIG. 5B), which can be metal gate-related, and a plurality of additional layers (510, 515, 520, 525, 530, and 535, FIG. 5B), which can include one or more metal gate-related layers. Alternatively, fifth gate stacks (501d, FIG. 5B) and the sixth gate stacks (501e, FIG. 5B) may be configured differently and may be used in poly-gate procedures. In addition, the fourth SQNB procedure can use the pattern in the previously modified gate-width control features (540d, FIG. 5B) and/or the pattern in the previously modified third hard mask features (545d, FIG. 5B) to create a substantially similar pattern of processed (etched) metal gate features 520e as shown in the sixth gate stack (501e, FIG. 5B). Alternatively, the sixth gate stack (501e, FIG. 5B) may be configured differently after the fourth SQNB procedure is performed.

During the fourth SQNB procedure, fourth upper plasma can be created using a fourth plasma generation gas in upper plasma region at fourth upper plasma potential. In various examples, the fourth plasma generation gas can include Ar, CF₄, F₂, O₂, N₂, CO, C₄F₈, C₅F₈, C₄F₆, CHF₃, N₂/H₂, or HBr, or any combination of two or more thereof. The plurality of first gas distribution elements (347, FIG. 3) can provide the fourth plasma generation gas to different regions of the upper plasma region (312, FIG. 3) using different flow rates.

In some embodiments, the upper multi-position switch (342, FIG. 3) can be used to couple the upper DC conductive electrode (311, FIG. 3) to a ground potential during some parts of the fourth SQNB procedure, and the upper multi-position switch (342, FIG. 3) can be used to couple the upper DC conductive electrode (311, FIG. 3) to the upper power supply (340, FIG. 3) during other parts of the fourth SQNB procedure to control the fourth upper plasma potential. In other embodiments, the upper multi-position switch (342, FIG. 3) can be used to couple the upper DC conductive electrode (311, FIG. 3) to a ground potential during substantially all of the fourth SQNB procedure to control the fourth upper plasma potential. In some other embodiments, the upper multi-position switch (342, FIG. 3) can be used to couple the upper DC conductive electrode (311, FIG. 3) to the upper power supply (340, FIG. 3) during substantially all of the fourth SQNB procedure to control the fourth upper plasma potential. For example, the upper power supply (340, FIG. 3) can provide DC power and/or AC power, and the output from the upper power supply (340, FIG. 3) can be constant, varied, pulsed, stepped, and/or ramped to control the fourth upper plasma potential during the fourth SQNB procedures.

A fourth SQNB processing plasma can also be formed in a switchable plasma region at a fourth SQNB processing plasma potential using electron flux from the fourth upper plasma. Electron flux from the fourth upper plasma in the upper plasma region passes from the plasma generation chamber through a separation member to a SQNB process chamber where the fourth SQNB processing plasma can be created. As illustrated in FIGS. 2A, 2B, and 3, the switchable plasma region may be located in a SQNB process chamber, wherein one or more openings or passages in the separation member disposed between the plasma generation chamber and the SQNB process chamber facilitate the transport or supply of electrons from the upper plasma region to the switchable plasma region.

In addition, the fourth SQNB processing plasma potential can be elevated above the fourth upper plasma potential to control the electron flux. The fourth upper plasma in the upper plasma region may be a boundary-driven plasma (i.e., the plasma boundary has a substantive influence on the respective plasma potential), wherein part or the entire boundary in contact with the fourth upper plasma is coupled to DC ground. Additionally, the fourth SQNB processing plasma in the switchable plasma region may be boundary-driven plasma, wherein part or the entire boundary in contact with the fourth SQNB processing plasma is coupled to a DC voltage source at +VDC. The elevation of the fourth SQNB processing plasma potential above the fourth upper plasma potential may be performed using any one or combination of the embodiments provided in FIGS. 2A, 2B, and 3.

In some alternate embodiments, the lower multi-position switch 382, FIG. 3) can be used to couple the lower bias electrode (317, FIG. 3) to a ground potential during some parts of the fourth SQNB procedure, and the lower multi-position switch (382, FIG. 3) can be used to couple the lower bias electrode (317, FIG. 3) to the bias power supply (380, FIG. 3) during other parts of the fourth SQNB procedure to control the fourth SQNB processing plasma potential. In other alternate embodiments, the lower multi-position switch (382, FIG. 3) can be used to couple the lower bias electrode (317, FIG. 3) to a ground potential during substantially all of the fourth SQNB procedure to control the fourth SQNB processing plasma potential. In some other alternate embodiments, the lower multi-position switch (382, FIG. 3) can be used to couple the lower bias electrode (317, FIG. 3) to the bias power supply (380, FIG. 3) during substantially all of the fourth SQNB procedure to control the fourth SQNB processing plasma potential. For example, the bias power supply (380, FIG. 3) can provide DC power and/or AC power, and the output from the bias power supply (380, FIG. 3) can be constant, varied, pulsed, stepped, and/or ramped to control the fourth SQNB processing plasma potential during the fourth SQNB procedures.

Furthermore, the pressure in the SQNB process chamber can be controlled by pumping the SQNB process chamber and by controlling the flow rate for the fourth SQNB process gases entering the SQNB process chamber during the fourth SQNB procedure. In various examples, the fourth SQNB process gases can include Ar, CF₄, F₂, O₂, N₂, CO, C₄F₈, C₅F₈, C₄F₆, CHF₃, N₂/H₂, or HBr, or any combination of two or more thereof. The plurality of second gas distribution elements (357, FIG. 3) can provide one or more of the fourth SQNB process gases to different regions of the switchable plasma region (352, FIG. 3) using different flow rates. The fifth gate stacks (501d, FIG. 5B) on the patterned substrate can be exposed to the fourth SQNB processing plasma in the switchable plasma region thereby creating the sixth gate stacks (501e, FIG. 5B). The exposure of the substrate to the fourth SQNB processing plasma may comprise exposing the substrate to a mono-energetic space-charge neutralized neutral beam activated chemical process.

In some additional embodiments, the first multi-position switch (332, FIG. 3) can be used to couple the switchable substrate holder (320, FIG. 3) to a ground potential during some parts of the fourth SQNB procedure, the first multi-position switch (332, FIG. 3) can be used to isolate the switchable substrate holder (320, FIG. 3) to during other parts of the fourth SQNB procedure, and/or the first multi-position switch (332, FIG. 3) can be used to couple the switchable substrate holder (320, FIG. 3) to the bias power supply (380, FIG. 3) during still other parts of the fourth SQNB procedure to control the fourth SQNB processing plasma. In other additional embodiments, the first multi-position switch (332, FIG. 3) can be used to couple the switchable substrate holder (320, FIG. 3) to a ground potential during substantially all of the fourth SQNB procedure to control the fourth SQNB processing plasma. In still other additional embodiments, the first multi-position switch (332, FIG. 3) can be used to isolate the switchable substrate holder (320, FIG. 3) during substantially all of the fourth SQNB procedure to control the fourth SQNB processing plasma. In some other additional embodiments, the first multi-position switch (332, FIG. 3) can be used to couple the switchable substrate holder (320, FIG. 3) to the bias power supply (380, FIG. 3) during substantially all of the fourth SQNB procedure to control the fourth SQNB processing plasma.

In 445, data from the first processing sequence can be stored as real-time and/or historical data.

In 450, procedure 400 can end.

When a send-ahead substrate is processed using a SQNB masking layer modification procedure, the processed send-ahead substrate can include a plurality of modified masking features and the at least one modified periodic structure. When measurement data is required, the send-ahead substrate can be transferred to the evaluation subsystem (160, FIG. 1), and measurement data can be obtained for the processed send-ahead substrate using ODP techniques and the at least one modified periodic structure. In addition, risk data for the SQNB masking layer modification procedure can be determined by comparing the measurement data to first limits for the SQNB masking layer modification procedure. In some examples, risk data can be determined for a set (lot) of patterned substrates using the first risk data for the SQNB masking layer modification procedure. In addition, confidence data can be determined for the SQNB masking layer modification procedure. When the risk data is not less than a first risk limit, one or more corrective actions can be performed.

When a send-ahead substrate is processed using a SQNB “feature-forming” procedure, the processed send-ahead substrate can include a plurality of processed masking features and the at least one processed periodic structure. When measurement data is required, the send-ahead substrate can be transferred to the evaluation subsystem (160, FIG. 1), and measurement data can be obtained for the processed send-ahead substrate using ODP techniques and the at least one processed periodic structure. In addition, risk data for the SQNB “feature-forming” procedure can be determined by comparing the measurement data to first limits for the SQNB “feature-forming” procedure. In some examples, risk data can be determined for a set (lot) of patterned substrates using the first risk data for the SQNB “feature-forming” procedure. In addition, confidence data can be determined for the SQNB “feature-forming” procedure. When the risk data is not less than a first risk limit, one or more corrective actions can be performed.

In some examples, corrective actions can include stopping the processing, pausing the processing, re-evaluating one or more of the substrates, re-measuring one or more of the substrates, re-inspecting one or more of the substrates, re-working one or more of the substrates, storing one or more of the substrates, cleaning one or more of the substrates, delaying one or more of the substrates, or stripping one or more of the substrates, or any combination thereof.

FIGS. 5A and 5B illustrate exemplary views of a first processing sequence for creating metal gate structures using at least one Switchable Quasi-Neutral Beam (SQNB) system (300, FIG. 3) in accordance with embodiments of the invention. In FIG. 5A, three exemplary gate stacks (501, 501a, and 501b) are shown that can be used to illustrate a first processing sequence 500A. In FIG. 5B, three other exemplary gate stacks (501c, 501d, and 501e) are shown that can be used to illustrate a second processing sequence 500B. Alternatively, a different number of gates stacks, a different number of layers, and different configurations may be used.

With reference to FIG. 5A, the first gate stack 501 can be an exemplary view of the results from a developing procedure or an evaluation procedure; the second gate stack 501a can be an exemplary view of the results from a first masking layer modification procedure; and the third gate stack 501b can be an exemplary view of the results from a first feature-forming and/or feature-modification procedure. Alternatively, a different number of gate stacks may be shown.

The first gate stack 501 can include a substrate layer 510, an interface layer 515, a metal gate layer 520, a first hard mask layer 525, a silicon-containing layer 530, a second hard mask layer 535, a gate-control layer 540, a third hard mask layer 545, and a plurality of masking features 550. In various embodiments, the substrate layer 510 can include a semiconductor material; the interface layer 515 can include isolation material; the metal gate layer 520 can include metallic material; the first hard mask layer 525 can include TiN; the silicon-containing layer 530 can include amorphous silicon (a-Si); the second hard mask layer 535 can include Tetraethyl Orthosilicate, (TEOS) (Si(OC₂H₅)₄); the gate-control layer 540 can include an gate-control material; the third hard mask layer 545 can include silicon-containing anti-reflective coating (SiARC) material; and the masking features 550 can include photoresist material 551. In other embodiments, the substrate layer 510 can include glass material, ceramic material, plastic material, dielectric material, and/or metallic material. For example, the semiconductor material can include silicon, and/or gallium arsenide; the metallic material can include aluminum (Al), copper (Cu), silver (Ag), gold (Au), ruthenium (Ru), nickel (Ni), cobalt (Co), and/or metallic oxides such as HfO₂; and the photoresist material can include 157 nm photoresist or 193 nm photoresist material.

The substrate layer 510 can have a height (thickness) 513 that can vary from approximately 25 nm and to approximately 200 nm; the interface layer 515 can have a height (thickness) 518 that can vary from approximately 2 nm and to approximately 10 nm; the metal gate layer 520 can have a height (thickness) 523 that can vary from approximately 20 nm and to approximately 50 nm; the first hard mask layer 525 can have a height (thickness) 528 that can vary from approximately 15 nm and to approximately 40 nm; the silicon-containing layer 530 can have a height (thickness) 533 that can vary from approximately 25 nm and to approximately 60 nm; the second hard mask layer 535 can have a height (thickness) 538 that can vary from approximately 5 nm and to approximately 20 nm; the gate-control layer 540 can have a height (thickness)) 543 that can vary from approximately 50 nm and to approximately 300 nm; the third hard mask layer 545 can have a height (thickness) 548 that can vary from approximately 15 nm and to approximately 60 nm; and the masking features 550 can have a height (thickness) 553 that can vary from approximately 30 nm and to approximately 400 nm. In addition, the masking features 550 can have a feature width 552 that can vary from approximately 30 nm and to approximately 400 nm and can have a separation width 554 that can vary from approximately 30 nm and to approximately 400 nm.

During the first processing sequence 500A and the second processing sequence 500B, one or more SQNB procedures can be performed, and the pattern of masking features 550 can be used to create a plurality of processed metal gate features 520e when the metal gate layer 520 is processed. For example, the masking layer modification process time, the masking layer modification process endpoint time, and the photoresist profile parameters can be used as control variables during the SQNB masking layer modification procedures, and the etching time, the etching endpoint time, and the modified photoresist profile parameters can be used as control variables during the SQNB processing procedures. In addition, the CDs (522e, 523e, and 524e) and/or the SWA data for the processed metal gate features 520e can be used as control variables during one or more of the processing procedures in the first processing sequence 500A and/or second processing sequence 500B. One or more of the subsystems (110, 120, 130, 140, 150, 160, and 170, FIG. 1) can provide additional control variables that can be used to determine the CDs (522e, 523e, and 524e) and/or the SWA data for the processed metal gate features 520e.

Referring still to FIG. 5A, a second gate stack 501a is shown that includes a substrate layer 510, an interface layer 515, a metal gate layer 520, a first hard mask layer 525, a silicon-containing layer 530, a second hard mask layer 535, a gate-control layer 540, a third hard mask layer 545, and a pattern of modified masking features 550a.

In various embodiments, the substrate layer 510 can include a semiconductor material; the interface layer 515 can include isolation material; the metal gate layer 520 can include metallic material; the first hard mask layer 525 can include TiN; the silicon-containing layer 530 can include amorphous silicon (a-Si); the second hard mask layer 535 can include TEOS; the gate-control layer 540 can include an gate-control material; the third hard mask layer 545 can include silicon-containing anti-reflective coating (SiARC) material; and the hardened soft mask features 550a can include photoresist material 551 and cured/hardened photoresist material 551a.

The third hard mask layer 545a can have a height (thickness) 548a that can vary from approximately 15 nm and to approximately 60 nm; and the modified masking features 550a can have a height (thickness) 553a that can vary from approximately 30 nm and to approximately 300 nm. The modified masking features 550a can have a feature width 552a that can vary from approximately 30 nm and to approximately 400 nm and can have a separation width 554a that can vary from approximately 30 nm and to approximately 400 nm. In addition, the thickness of the cured/hardened 193 nm photoresist material 551a can vary from approximately 1 nm and to approximately 10 nm.

Still referring to FIG. 5A, a third gate stack 501b is shown that can be created using a second SQNB processing procedure. Alternatively, a different processing procedure can be performed that does not require a SQNB source. The third gate stack 501b can include a substrate layer 510, an interface layer 515, a metal gate layer 520, a first hard mask layer 525, a silicon-containing layer 530, a second hard mask layer 535, a plurality of processed gate-width control features 540b, and a plurality of processed third hard mask features 545b. During the second SQNB procedure, the plurality of modified masking features 550a can be used to create the plurality of new (processed) gate-width control features 540b, and a plurality of new (processed) third hard mask features 545b. Alternatively, the plurality of new (processed) gate-width control features 540b may be configured differently, and a plurality of new (processed) third hard mask features 545b may not be present.

In various embodiments, the substrate layer 510 can include a semiconductor material; the interface layer 515 can include isolation material; the metal gate layer 520 can include metallic material; the first hard mask layer 525 can include TiN; the silicon-containing layer 530 can include amorphous silicon (a-Si); the second hard mask layer 535 can include TEOS; the processed gate-width control features 540b can include processed gate-width control material 541b; and the processed third hard mask features 545b can include processed SiARC material 546b.

The processed third hard mask features 545b, when they are present, can have a height (thickness) 548b that can vary from approximately 0 nm and to approximately 60 nm. The processed third hard mask features 545b can have a feature width 547b that can vary from approximately 30 nm and to approximately 300 nm and can have a separation width 549b that can vary from approximately 30 nm and to approximately 300 nm.

The processed gate-width control features 540b can have a height (thickness) 543b that can vary from approximately 30 nm and to approximately 300 nm. The processed gate-width control features 540b can have a feature width 542b that can vary from approximately 30 nm and to approximately 300 nm and can have a separation width 544b that can vary from approximately 30 nm and to approximately 300 nm.

FIG. 5B illustrates another processing sequence in accordance with embodiments of the invention. In the illustrated embodiment, a second SQNB processing sequence 500B is illustrated and the second SQNB processing sequence can include a third SQNB procedure and a fourth SQNB procedure. For example, the third SQNB procedure can include a second masking layer modification procedure, and the fourth SQNB procedure can include a second feature-forming procedure. With reference to FIG. 5B, the fourth gate stack 501c can be an exemplary view of the results from a first processing sequence or a second evaluation procedure; the fifth gate stack 501d can be an exemplary view of the results from third SQNB procedures (additional masking layer modification procedures); and the sixth gate stack 501e can be an exemplary view of the results from fourth SQNB procedures (additional feature-forming procedures). Alternatively, a different number of gate stacks may be shown.

In FIG. 5B, a fourth gate stack 501c is shown that can be created using a first SQNB processing sequence. Alternatively, a different processing sequence can be performed that does not require a SQNB source. The fourth gate stack 501c can include a substrate layer 510, an interface layer 515, a metal gate layer 520, a first hard mask layer 525, a silicon-containing layer 530, a second hard mask layer 535, a plurality of previously-processed gate-width control features 540c, and a plurality of previously-processed third hard mask features 545c. During the second processing sequence 500B, the plurality of previously-processed gate-width control features 540c, and/or the plurality of previously-processed third hard mask features 545c can be used to create the plurality of etched metal gate features 520e. Alternatively, the plurality of previously-processed gate-width control features 540c may be configured differently, and the plurality of previously-etched third hard mask features 545c may not be present.

In various embodiments, the substrate layer 510 can include a semiconductor material; the interface layer 515 can include isolation material; the metal gate layer 520 can include metallic material; the first hard mask layer 525 can include TiN; the silicon-containing layer 530 can include amorphous silicon (a-Si); the second hard mask layer 535 can include TEOS; the previously-processed gate-width control features 540c can include previously-processed gate-width control material 541c; and the previously-processed third hard mask features 545c can include previously-processed SiARC material 546c. In other embodiments, the substrate layer 510 can include glass material, ceramic material, plastic material, dielectric material, and/or metallic material. For example, the semiconductor material can include silicon, and/or gallium arsenide; the metallic material can include aluminum (Al), copper (Cu), silver (Ag), gold (Au), ruthenium (Ru), nickel (Ni), cobalt (Co), and/or metallic oxides such as HfO₂; and the photoresist material can include 157 nm photoresist or 193 nm photoresist material.

The previously-processed gate-width control features 540c can have a height (thickness)) 543c that can vary from approximately 30 nm and to approximately 300 nm; the previously-processed third hard mask features 545c can have a height (thickness) 548c that can vary from approximately 0 nm and to approximately 60 nm. The previously-processed third hard mask features 545c can have a feature width 547c that can vary from approximately 30 nm and to approximately 300 nm and can have a separation width 549c that can vary from approximately 30 nm and to approximately 300 nm. In addition, the previously-processed gate-width control features 540c can have a feature width 542c that can vary from approximately 30 nm and to approximately 300 nm and can have a separation width 544c that can vary from approximately 30 nm and to approximately 300 nm. The evaluation subsystem (160, FIG. 1) can be used to determine the CDs (542c, 543c, and 544c) and SWA data for the previously-processed gate-width control features 540c and/or can be used to determine the CDs (547c, 548c, and 549c) and SWA data for the previously-processed third hard mask features 545c when they are present.

During the second processing sequence 500B, one or more SQNB procedures can be performed, and the previously-processed third hard mask features 545c and/or the previously-processed gate-width control features 540c can be used to create a plurality of etched metal gate features 520e when the metal gate layer 520 is etched. In addition, the CDs (522e, 523e, and 524e) for the etched metal gate features 520e can be established during one or more of the etching procedures in the second processing sequence 500B and/or the first processing sequence 500A and can range from approximately 20 nm to approximately 300 nm. The evaluation subsystem (160, FIG. 1) can be used to determine the CDs (522e, 523e, and 524e) and the SWA data for the etched metal gate features 520e. Alternatively, the CDs (522e, 523e, and 524e) may be associated with the etched poly-gate features 520e and may range from approximately 20 nm to approximately 100 nm.

Referring still to FIG. 5B, a fifth gate stack 501d is shown that includes a substrate layer 510, an interface layer 515, a metal gate layer 520, a first hard mask layer 525, a silicon-containing layer 530, a second hard mask layer 535, a plurality of modified gate-width control features 540d, and a plurality of modified third hard mask features 545d. Alternatively, the plurality of modified third hard mask features 545d may not be present.

In various embodiments, the substrate layer 510 can include a semiconductor material; the interface layer 515 can include isolation material; the metal gate layer 520 can include metallic material; the first hard mask layer 525 can include TiN; the plurality of modified gate-width control features 540d can include gate-width control material 541c and modified gate-width control material 541d; and the plurality of modified third hard mask features 545d can include modified (cured and/or hardened) SiARC material 546d and SiARC modified (cured and/or hardened) material 546c.

The plurality of plurality of modified third hard mask features 545d can have a height (thickness) 548d that can vary from approximately 0 nm and to approximately 60 nm; can have a feature width 547d that can vary from approximately 30 nm and to approximately 300 nm and can have a separation width 549d that can vary from approximately 30 nm and to approximately 300 nm. In addition, the thickness of the modified third hard mask material 546d can vary from approximately 1 nm and to approximately 10 nm. The modified gate-width control features 540d can have a height (thickness) 543d that can vary from approximately 30 nm and to approximately 300 nm; can have a feature width 542d that can vary from approximately 30 nm and to approximately 300 nm and can have a separation width 544d that can vary from approximately 30 nm and to approximately 300 nm. In addition, the thickness of the modified gate-width control material 541d can vary from approximately 1 nm and to approximately 10 nm.

Still referring to FIG. 5B, a sixth gate stack 501e is shown that can be created using a fourth SQNB procedure. Alternatively, a different feature-forming procedure can be performed that does not require a SQNB source. The sixth gate stack 501e can include a substrate layer 510, a processed interface layer 515e, and a plurality of processed (etched) metal gate features 520e. During the fourth SQNB procedure, the modified third hard mask features 545d and/or the modified gate-width control features 540d can be used to create the plurality of processed (etched) metal gate features 520e. Alternatively, the plurality of modified gate-width control features 540d may be configured differently, and the modified third hard mask features 545d may not be present.

In some examples, the substrate layer 510 can include a semiconductor material; the processed interface layer 515e can include processed isolation material; the etched metal gate features 520e can include etched metal oxide material, such as HfO₂ material. The etched metal gate features 520e can have a (feature width) CD 522e that can vary from approximately 30 nm to approximately 100 nm, can have a height (thickness) 523e that can vary from approximately 10 nm to approximately 60 nm, and can have a separation width 524e that can vary from approximately 30 nm to approximately 400 nm.

During some alternate SQNB processing sequences, only gate stacks 501 and 501e are created, and the CDs (522e, 523e, 524e) and SWA data associated with the metal gate features 520e can be determined using the CDs (552, 553, 554) and the SWA data associated with the gate-related masking features 550. For example, one or more SQNB etching procedures can be performed, and the gate stacks 501 and 501e can be configured differently. In addition, one or more of the layers (515, 520, 525, 530, 535, 540, and 545) may not be required or may be positioned differently.

During other alternate SQNB processing sequences, only gate stacks 501, 501a and 501e are created, and the CDs (522e, 523e, 524e) and SWA data associated with the metal gate features 520e can be determined using the CDs (552, 553, 554) and the SWA data associated with the gate-related masking features 550 and/or the using the CDs (552a, 553a, 554a) and the SWA data associated with the modified masking features 550a. For example, one or more SQNB etching procedures can be performed after one or more photoresist modification procedures have been performed, and the gate stacks 501, 501a, and 501e can be configured differently. In addition, one or more of the layers (515, 520, 525, 530, 535, 540, and 545) may not be required or may be positioned differently. In addition, the modified masking features 550a may include modified, cured, shrunk, protected, and/or hardened masking features.

During some other alternate SQNB processing sequences, only gate stacks 501c, 501d and 501e are created, and the CDs (522e, 523e, 524e) and SWA data associated with the metal gate features 520e can be determined using the CDs (547c, 548c, 549c) and the SWA data associated with the previously-processed third hard mask features 545c and/or the using the CDs (547d, 548d, 549d) and the SWA data associated with the modified third hard mask features 545d. For example, one or more SQNB etching procedures can be performed after one or more photoresist modification procedures have been performed, and the gate stacks 501c, 501d, and 501e can be configured differently. In addition, one or more of the layers (515, 520, 525, 530, 535, 540, and 545) may not be required or may be positioned differently. In addition, the modified masking features 550a may include modified, cured, shrunk, protected, and/or hardened masking features.

During still other alternate SQNB processing sequences, only gate stacks 501c, 501d and 501e are created, and the CDs (522e, 523e, 524e) and SWA data associated with the metal gate features 520e can be determined using the CDs (542c, 543c, 544c) and the SWA data associated with the previously-processed gate-width control features 540c and/or the using the CDs (542d, 543d, 544d) and the SWA data associated with the modified gate-width control features 540d. For example, one or more SQNB etching procedures can be performed after one or more photoresist modification procedures have been performed, and the gate stacks 501c, 501d, and 501e can be configured differently. In addition, one or more of the layers (515, 520, 525, 530, 535, 540, and 545) may not be required or may be positioned differently. In addition, the modified masking features 550a may include modified, cured, shrunk, protected, and/or hardened masking features.

During various SQNB masking layer modification procedures, the pressure in the plasma generation chamber (310, FIG. 3) can range from approximately 50 mT to approximately 100 mT; and the pressure in the SQNB process chamber (315, FIG. 3) can range from approximately 50 mT to approximately 100 mT. During various SQNB feature-forming procedures, the pressure in the plasma generation chamber (310, FIG. 3) can range from approximately 50 mT to approximately 100 mT; and the pressure in the SQNB process chamber (315, FIG. 3) can range from approximately 50 mT to approximately 100 mT.

During various SQNB masking layer modification procedures, a first RF power can be provided by the plasma generating source (360, FIG. 3) to the multi-turn inductive coils 362, and first RF power can vary from approximately 10 watts to approximately 1500 watts. During various SQNB feature-forming procedures, a second RF power can be provided by the plasma generating source (360, FIG. 3) to the multi-turn inductive coils 362, and the second RF power can vary from approximately 10 watts to approximately 1500 watts.

During various SQNB masking layer modification procedures, the voltage provided by the bias power supply (380, FIG. 3) can vary from approximately 0 volts to approximately 1500 volts. During various SQNB feature-forming procedures, the voltage provided by the bias power supply (380, FIG. 3) can vary from approximately 0 volts to approximately 1500 volts.

During some SQNB masking layer modification and/or feature-forming procedures, the upper gas supply system (345, FIG. 3) can provide Tetrafluoromethane (CF₄), and the CF₄ flow rate can vary between approximately 60 sccm and approximately 100 sccm. During other SQNB masking layer modification and/or feature-forming procedures, the upper gas supply system (345, FIG. 3) can provide Carbon Hydro-Trifluoride (CHF₃), and the CHF₃ flow rate can vary between approximately 40 sccm and approximately 60 sccm.

During some SQNB masking layer modification and/or feature-forming procedures, the temperature in the plasma generation chamber (310, FIG. 3) can vary from approximately 70 degrees Celsius to approximately 90 degrees Celsius; the chamber wall temperature in the plasma generation chamber (310, FIG. 3) can vary from approximately 50 degrees Celsius to approximately 70 degrees Celsius; the temperature in the SQNB process chamber (315, FIG. 3) can vary from approximately 10 degrees Celsius to approximately 30 degrees Celsius; the temperature at the center of the switchable substrate holder (320, FIG. 3) can vary from approximately 12 degrees Celsius to approximately 20 degrees Celsius; the temperature at the edge of the switchable substrate holder (320, FIG. 3) can vary from approximately 8 degrees Celsius to approximately 12 degrees Celsius; the center backside pressure for the switchable substrate holder (320, FIG. 3) can vary from approximately 5 Torr to approximately 15 Torr; the edge backside pressure for the switchable substrate holder (320, FIG. 3) can vary from approximately 27 Torr to approximately 33 Torr; and the processing time can vary from approximately 20 seconds to approximately 150 seconds. Alternatively, another gas may be required.

In alternate embodiments, during the first processing sequence 500A, a first SQNB feature-forming sequence can be performed after the first SQNB masking layer modification procedure is performed. For example, the first feature-forming sequence can include a first SiARC Etch procedure, and a first gate-control layer etching procedure, and the SiARC etching time, the SiARC endpoint time, the gate-control layer etching time, the gate-control layer endpoint time, and the etched photoresist profile parameters can be used as control variables during the first etching sequence. In addition, the SiARC etch procedure can be used to etch the SiARC layer 545a, and the first gate-control layer etching procedure can be used to etch the gate-control layer 540.

During the first Si-ARC layer etching procedure, the chamber pressure can range from approximately 12 mT to approximately 18 mT; the top power can vary from approximately 450 watts to approximately 550 watts; the lower power can vary from approximately 90 watts to approximately 110 watts; the ESC voltage can be set at approximately 2500 V; the Tetrafluoromethane (CF₄) flow rate can vary between approximately 60 sccm and approximately 100 sccm; the Carbon Hydro-Trifluoride (CHF₃) flow rate can vary between approximately 40 sccm and approximately 60 sccm; the top chamber temperature can vary from approximately 70 degrees Celsius to approximately 90 degrees Celsius; the chamber wall temperature can vary from approximately 50 degrees Celsius to approximately 70 degrees Celsius; the bottom chamber temperature can vary from approximately 10 degrees Celsius to approximately 30 degrees Celsius; the temperature at the center of the substrate holder can vary from approximately 12 degrees Celsius to approximately 20 degrees Celsius; the temperature at the edge of the substrate holder can vary from approximately 8 degrees Celsius to approximately 12 degrees Celsius; the center backside pressure for the substrate holder can vary from approximately 15 Torr to approximately 25 Torr; the edge backside pressure for the substrate holder can vary from approximately 27 Torr to approximately 33 Torr; and the processing time can vary from approximately 60 seconds to approximately 90 seconds.

During the first gate-control layer etching procedure, the chamber pressure can range from approximately 15 mT to approximately 25 mT; the top power can vary from approximately 150 watts to approximately 250 watts; the lower power can vary from approximately 90 watts to approximately 110 watts; the ESC voltage can be set at approximately 2500 V; the He flow rate can vary between approximately 150 sccm and approximately 250 sccm; the HBr flow rate can vary between approximately 25 sccm and approximately 35 sccm; the O₂ flow rate can vary between approximately 30 sccm and approximately 50 sccm; the CO₂ flow rate can vary between approximately 260 sccm and approximately 320 sccm; the top chamber temperature can vary from approximately 70 degrees Celsius to approximately 90 degrees Celsius; the chamber wall temperature can vary from approximately 50 degrees Celsius to approximately 70 degrees Celsius; the bottom chamber temperature can vary from approximately 10 degrees Celsius to approximately 30 degrees Celsius; the temperature at the center of the wafer holder can vary from approximately 12 degrees Celsius to approximately 20 degrees Celsius; the temperature at the edge of the wafer holder can vary from approximately 8 degrees Celsius to approximately 12 degrees Celsius; the center backside pressure for the wafer holder can vary from approximately 15 Torr to approximately 25 Torr; the edge backside pressure for the wafer holder can vary from approximately 27 Torr to approximately 33 Torr; and the processing time can vary from approximately 90 seconds to approximately 130 seconds.

During the first SiN (TEOS) layer etching procedure, the chamber pressure can range from approximately 35 mT to approximately 45 mT; the top power can vary from approximately 550 watts to approximately 650 watts; the lower power can vary from approximately 90 watts to approximately 110 watts; the ESC voltage can be set at approximately 2500 V; the O₂ flow rate can vary between approximately 3 sccm and approximately 7 sccm; the CF4 flow rate can vary between approximately 40 sccm and approximately 60 sccm; the CHF3 flow rate can vary between approximately 40 sccm and approximately 60 sccm; the top chamber temperature can vary from approximately 30 degrees Celsius to approximately 90 degrees Celsius; the chamber wall temperature can vary from approximately 50 degrees Celsius to approximately 70 degrees Celsius; the bottom chamber temperature can vary from approximately 30 degrees Celsius to approximately 50 degrees Celsius; the temperature at the center of the wafer holder can vary from approximately 25 degrees Celsius to approximately 35 degrees Celsius; the temperature at the edge of the wafer holder can vary from approximately 8 degrees Celsius to approximately 12 degrees Celsius; the center backside pressure for the wafer holder can vary from approximately 15 Torr to approximately 25 Torr; the edge backside pressure for the wafer holder can vary from approximately 27 Torr to approximately 33 Torr; and the processing time can vary from approximately 50 seconds to approximately 90 seconds.

During the first SiN Over-Etch (OE) procedure, the chamber pressure can range from approximately 35 mT to approximately 45 mT; the top power can vary from approximately 550 watts to approximately 650 watts; the lower power can vary from approximately 1250 watts to approximately 175 watts; the ESC voltage can be set at approximately 2500 V; the O2 flow rate can vary between approximately 3 sccm and approximately 7 sccm; the CF4 flow rate can vary between approximately 40 sccm and approximately 60 sccm; the CHF3 flow rate can vary between approximately 40 sccm and approximately 60 sccm; the top chamber temperature can vary from approximately 70 degrees Celsius to approximately 90 degrees Celsius; the chamber wall temperature can vary from approximately 50 degrees Celsius to approximately 70 degrees Celsius; the bottom chamber temperature can vary from approximately 10 degrees Celsius to approximately 30 degrees Celsius; the temperature at the center of the substrate holder can vary from approximately 12 degrees Celsius to approximately 20 degrees Celsius; the temperature at the edge of the substrate holder can vary from approximately 8 degrees Celsius to approximately 12 degrees Celsius; the center backside pressure for the substrate holder can vary from approximately 15 Torr to approximately 25 Torr; the edge backside pressure for the substrate holder can vary from approximately 27 Torr to approximately 33 Torr; and the processing time can vary from approximately 60 seconds to approximately 90 seconds.

In some examples, individual and/or total confidence values for the SQNB procedure can be compared to individual and/or total confidence limits. The processing of a set of substrates can continue, if one or more of the confidence limits are met, or corrective actions can be applied if one or more of the confidence limits are not met. Corrective actions can include establishing confidence values for one or more additional substrates in the set of substrates, comparing the confidence values for one or more of the additional substrates to additional confidence limits; and either continuing the SQNB procedure, if one or more of the additional confidence limits are met, or stopping the SQNB procedure, if one or more of the additional confidence limits are not met.

In other examples, individual and/or total risk values for the substrate can be compared to individual and/or total risk limits. The processing of a set of substrates can continue, if one or more of the risk limits are met, or corrective actions can be applied if one or more of the risk limits are not met. Corrective actions can include establishing risk values for one or more additional substrates in the set of substrates, comparing the risk values for one or more of the additional substrates to additional risk limits; and either continuing the SQNB procedure, if one or more of the additional risk limits are met, or stopping the SQNB procedure, if one or more of the additional risk limits are not met.

In other embodiments, one or more substrates can be processed using a verified SQNB procedure. When a verified SQNB procedure is used, one or more verified structures can be created on a substrate (“golden wafer”). When the substrate is examined, a test reference structure can be selected from a number of verified structures on the substrate. During the examination, examination data can be obtained from the test reference structure. A best estimate structure and associated best estimate data can be selected from the library that includes verified structures and associated data. One or more differences can be calculated between the test reference structure and the best estimate structure from the library, the differences can be compared to matching criteria, creation criteria, or product requirements, or any combination thereof. When matching criteria are used, the test reference structure can be identified as a member of the library, and the current substrate can be identified as a reference “golden” substrate if the matching criteria are met or exceeded. When creation criteria are used, the test reference structure can be identified as a new member of the library, and the current substrate can be identified as a verified reference substrate if the creation criteria are met. When product requirement data is used, the test reference structure can be identified as a verified structure, and the substrate can be identified as verified production substrate if one or more product requirements are met. Corrective actions can be applied if one or more of the criteria or product requirements are not met. Confidence data and/or risk data can be established for the SQNB procedures using the test reference structure data and the best estimate structure data.

When structures and/or features are produced and/or examined during SQNB procedures, accuracy and/or tolerance limits can be used. When these limits are not correct, refinement procedures can be performed. Alternatively, other procedures can be performed, other sites can be used, or other substrates can be used. When a refinement procedure is used, the refinement procedure can utilize bilinear refinement, Lagrange refinement, Cubic Spline refinement, Aitken refinement, weighted average refinement, multi-quadratic refinement, bi-cubic refinement, Turran refinement, wavelet refinement, Bessel's refinement, Everett refinement, finite-difference refinement, Gauss refinement, Hermite refinement, Newton's divided difference refinement, osculating refinement, or Thiele's refinement algorithm, or a combination thereof.

In some embodiments, the library data associated with SQNB procedures can include goodness of fit (GOF) data, creation rules data, measurement data, inspection data, verification data, map data, confidence data, accuracy data, process data, or uniformity data, or any combination thereof.

In some embodiments, the historical and/or real-time data can include substrate-related maps, process-related maps, damage-assessment maps, reference maps, measurement maps, prediction maps, risk maps, inspection maps, verification maps, evaluation maps, particle maps, and/or confidence maps for one or more substrates. In addition, some SQNB procedures may use substrate maps that can include one or more Goodness Of Fit (GOF) maps, one or more thickness maps, one or more gate-related maps, one or more Critical Dimension (CD) maps, one or more CD profile maps, one or more material related maps, one or more structure-related maps, one or more sidewall angle maps, one or more differential width maps, or a combination thereof.

When substrate maps are created and/or modified, values may not be calculated and/or required for the entire substrate, and a substrate map may include data for one or more sites, one or more chip/dies, one or more different areas, and/or one or more differently shaped areas. For example, a SQNB system or chamber may have unique characteristics that may affect the quality of the processing results in certain areas of the substrate. In addition, a manufacturer may allow less accurate process and/or evaluation data for chips/dies in one or more regions of the substrate to maximize yield. When a value in a map is close to a limit, the confidence value may be lower than when the value in a map is not close to a limit. In addition, the accuracy values can be weighted for different chips/dies and/or different areas of the substrate. For example, a higher confidence weight can be assigned to the accuracy calculations and/or accuracy data associated with one or more of the previously used evaluation sites.

In addition, process result, measurement, inspection, verification, evaluation, and/or prediction maps associated with one or more processes may be used to calculate a confidence map for a substrate. For example, values from another map may be used as weighting factors.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

Thus, the description is not intended to limit the invention and the configuration, operation, and behavior of the present invention has been described with the understanding that modifications and variations of the embodiments are possible, given the level of detail present herein. Accordingly, the preceding detailed description is not mean or intended to, in any way, limit the invention—rather the scope of the invention is defined by the appended claims.

1. A Switchable Quasi-Neutral Beam (SQNB) system comprising:
plasma generation chamber having an upper plasma region configured to establish a first upper plasma at a first upper plasma potential during a first Switchable Quasi-Neutral Beam (SQNB) procedure and configured to produce a second upper plasma at a second upper plasma potential during a second Switchable Quasi-Neutral Beam (SQNB) procedure;
Switchable Quasi-Neutral Beam (SQNB) process chamber having a switchable plasma region configured to establish a first SQNB processing plasma at a first SQNB processing plasma potential during the first SQNB procedure and configured to produce a second SQNB processing plasma at a second SQNB processing plasma potential during the second SQNB procedure;
a separation member disposed between the plasma generation chamber and the SQNB process chamber, wherein the separation member comprises one or more openings configured to create a first group of beams in the switchable plasma region during the first SQNB procedure and are configured to create a second group of beams in the switchable plasma region during the second SQNB procedure, wherein the first group of beams comprise a first electron flux from the upper plasma region established to form the first SQNB processing plasma during the first SQNB procedure and the second group of beams comprise a second electron flux from the upper plasma region established to form the second SQNB plasma during the second SQNB procedure;
a switchable substrate holder configured to support a patterned substrate in the SQNB process chamber, the switchable substrate holder being coupled to a ground potential during the first SQNB procedure and being isolated from the ground potential during the second SQNB procedure;
a bias electrode system configured to surround the switchable substrate holder in the SQNB process chamber, the bias electrode system being configured to elevate the first SQNB processing plasma potential above the first upper plasma potential in order to control the first electron flux during the first SQNB procedure and being configured to elevate the second SQNB processing plasma potential above the second upper plasma potential in order to control the second electron flux during the second SQNB procedure; and
a controller coupled to one or more first sensors configured in the plasma generation chamber, at least one second sensor configured in the SQNB process chamber, the bias electrode system, and the switchable substrate holder, the controller being configured to determine material data for the patterned substrate and establish the first SQNB procedure and the second SQNB procedure using the determined material data.

2. The SQNB system of claim 1, further comprising:
one or more first gas distribution elements configured within the plasma generation chamber, wherein at least one of the first gas distribution elements is configured to provide a first plasma generation gas at a first flow rate to the upper plasma region during the first SQNB procedure, and wherein one or more of the first gas distribution elements are configured to provide a second plasma generation gas at a second flow rate to the upper plasma region during the second SQNB procedure; and
one or more upper gas supply systems coupled to the one or more of the first gas distribution elements using at least one first supply line.

3. The SQNB system of claim 2, wherein the first plasma generation gas and/or the second plasma generation gas include a fluorocarbon gas and an inert gas, the fluorocarbon gas comprising C₄F₆, C₄F₈, C₅F₈, CHF₃ or CF₄, or any combination thereof, and the inert gas comprising Argon (Ar), Helium (He), Krypton (Kr), Neon (Ne), Radon (Rn), or Xenon (Xe), or any combination thereof.

4. The SQNB system of claim 1, further comprising:
one or more switchable gas distribution elements configured within the SQNB process chamber, wherein at least one of the switchable gas distribution elements is configured to provide a first SQNB process gas to the switchable plasma region during the first SQNB procedure, and wherein one or more of the switchable gas distribution elements are configured to provide a second SQNB process gas to the switchable plasma region during the second SQNB procedure; and
one or more switchable gas supply systems coupled to the one or more of the switchable gas distribution elements using at least one second supply line.

5. The SQNB system of claim 4, wherein the first SQNB process gas and/or the second SQNB process gas include a fluorocarbon gas and an inert gas, the fluorocarbon gas comprising C₄F₆, C₄F₈, C₅F₈, CHF₃, or CF₄, or any combination thereof, and the inert gas comprising Argon (Ar), Helium (He), Krypton (Kr), Neon (Ne), Radon (Rn), or Xenon (Xe), or any combination thereof.

6. The SQNB system of claim 1, further comprising:
one or more inductive coils coupled to the plasma generation chamber, at least one of the inductive coils being configured to produce the first upper plasma at the first upper plasma potential in the upper plasma region; and
a plasma generation source coupled to one or more of the inductive coils using at least one match network.

7. The SQNB system of claim 6, wherein the plasma generation source comprises a radio frequency (RF) generator, wherein a RF power from the plasma generation source ranges from about 10 watts to about 1000 watts and a RF frequency for the plasma generation source ranges from about 0.1 MHz to about 100 MHz.

8. The SQNB system of claim 6, wherein an output from the plasma generation source is configured to be modulated, varied, pulsed, stepped, ramped, or held constant, or any combination thereof during the first and/or second SQNB procedure.

9. The SQNB system of claim 1, further comprising:
an upper multi-position switch coupled to one or more upper DC conductive electrodes configured in the plasma generation chamber using one or more upper feed-thru elements; and
an upper power supply coupled to the upper multi-position switch, the upper multi-position switch having a common port coupled to at least one of the upper feed-thru elements, a first switchable port coupled to the ground potential, and a second switchable port coupled to the upper power supply, the upper multi-position switch having a first position configured to couple at least one of the upper DC conductive electrodes to the ground potential and a second position configured to couple one or more of the upper DC conductive electrodes to the upper power supply.

10. The SQNB system of claim 9, wherein the upper power supply is configured to provide DC power, or AC power, or any combination thereof, and an output from the upper power supply is configured to be varied, pulsed, stepped, ramped, or held constant, or any combination thereof during the first and/or second SQNB procedure.

11. The SQNB system of claim 1, further comprising:
a lower multi-position switch coupled to one or more lower bias electrodes configured in the SQNB process chamber using one or more lower feed-thru elements; and
a bias power supply coupled to the lower multi-position switch, the lower multi-position switch having a common port coupled to at least one of the lower feed-thru elements, a first switchable port coupled to the ground potential, and a second switchable port coupled to the bias power supply, the lower multi-position switch having a first position configured to couple at least one of the lower bias electrodes to the ground potential and a second position configured to couple one or more of the lower bias electrodes to the bias power supply.

12. The SQNB system of claim 11, wherein the bias power supply is configured to provide DC power, or AC power, or any combination thereof, and an output from the bias power supply is configured to be varied, pulsed, stepped, ramped, or held constant, or any combination thereof during the first and/or second SQNB procedure.

13. The SQNB system of claim 11, wherein an upper power supply is configured to provide a DC voltage to at least one upper DC conductive electrode coupled in the plasma generation chamber that is less than a bias DC voltage provided to a lower bias electrode in the SQNB process chamber by the bias power supply.

14. The SQNB system of claim 1, further comprising:
a first multi-position switch coupled to one or more substrate bias electrodes configured in the switchable substrate holder using one or more first feed-thru elements; and
a bias generator coupled to the first multi-position switch using a filter network, the first multi-position switch having a common port coupled to at least one of the substrate bias electrodes, a first switchable port coupled to the ground potential, and a second switchable port coupled to the filter network, the first multi-position switch having a first position configured to couple at least one of the substrate bias electrodes to the ground potential, a second position configured to couple one or more of the substrate bias electrodes to the bias generator using the filter network, and a third position configured to isolate at least one of the substrate bias electrodes from the ground potential.

15. The SQNB system of claim 14, wherein the bias generator comprises a radio frequency (RF) generator, wherein a first RF power from the bias generator ranges from about 10 watts to about 1000 watts and a first RF frequency for the bias generator ranges from about 0.1 MHz to about 100 MHz during the first and/or second SQNB procedure.

16. The SQNB system of claim 14, wherein the bias generator provides DC power, or AC power, or any combination thereof, and an output from the bias generator is varied, is pulsed, is stepped, is ramped, or is held constant, or any combination thereof during the first and/or second SQNB procedure.

17. The SQNB system of claim 1, wherein at least one of the first sensors is configured to detect an upper plasma state in the plasma generation chamber during the first and/or second SQNB procedure, and one or more second sensors are configured to detect a lower plasma state in the SQNB process chamber during the first and/or second SQNB procedure.

18. The SQNB system of claim 1, wherein the switchable substrate holder comprises dual backside gas elements coupled to a backside gas system and temperature control elements coupled to a temperature control system configured to establish a first edge temperature and a first center temperature for the patterned substrate, wherein the first edge temperature and the first center temperature are between about 0 degrees Celsius and about 100 degrees Celsius.

19. The SQNB system of claim 1, wherein the first SQNB procedure creates a modified masking layer on the patterned substrate and the second SQNB procedure uses the modified masking layer to create new features on the patterned substrate.

20. A method for processing a substrate using a Switchable Quasi-Neutral Beam (SQNB) source, comprising:
positioning a patterned substrate on a switchable substrate holder configured to support the patterned substrate in a switchable processing chamber;
connecting the switchable substrate holder to a ground potential during a first Switchable Quasi-Neutral Beam (SQNB) procedure;
modifying a masking layer on the patterned substrate using a first space-charge neutralized neutral beam from the SQNB source during the first SQNB procedure;
isolating the switchable substrate holder from the ground potential during a second SQNB procedure; and
creating new features on the patterned substrate using a second space-charge neutralized neutral beam from the SQNB source during the second SQNB procedure.
